(19) United States
(12) Patent Application Publication
(10) Pub. No.: US 2015/0364716 A1
(43) Pub. Date: Dec. 17, 2015

(54) ORGANIC LIGHT EMITTING DEVICE AND METHOD OF MANUFACTURING THE DEVICE

(71) Applicant: CANON KABUSHIKI KAISHA, Tokyo (JP)

(72) Inventors: Satoru Shiobara, Funabashi-shi (JP); Kiyofumi Sakaguchi, Miura-gun (JP); Yojiro Matsuda, Kawasaki-shi (JP); Nobutaka Mizuno, Tokyo (JP)

(21) Appl. No.: 14/734,567

(22) Filed: Jun. 9, 2015

(30) Foreign Application Priority Data
Jun. 17, 2014 (JP) 2014-124480
Jun. 17, 2014 (JP) 2014-124481
Apr. 1, 2015 (JP) 2015-075000

(51) Int. Cl. H01L 51/52; H05B 33/08; G09G 3/32; H01L 51/56

(52) U.S. Cl. CPC H01L 51/5237; H01L 51/529; H01L 51/5206; H01L 51/5221; H01L 51/56; H05B 33/0896; G09G 3/3208; H01L 2251/55

(57) ABSTRACT

Provided is an organic light emitting device, including: a substrate; and a lower electrode, an organic compound layer including an emission layer, and an upper electrode sequentially provided on the substrate, in which: the organic compound layer covers the lower electrode; the upper electrode covers the organic compound layer; the upper electrode is electrically connected to a wiring connecting portion provided in the substrate; and when an angle formed between a tilt of a section of an end in at least a partial region of the organic compound layer and a surface of the substrate is represented by θ₁, the following formulas (1) and (2) are satisfied:

tan(θ₁)=d₁/d₂ (1)

tan(θ₁)≧0.2 (2)

in the formula (1), d₁ represents a thickness of the organic compound layer and d₂ represents a taper width of the section of the end of the organic compound layer.

### BACKGROUND OF THE INVENTION

1. Field of the Invention

The present invention relates to an organic light emitting device and a method of manufacturing the organic light emitting device.

2. Description of the Related Art

Organic light emitting devices are devices in which a plurality of organic light emitting elements are arranged in lines or in a matrix on a base material or a substrate. The organic light emitting devices can be used for multicolor display when the organic light emitting elements are arranged so that one pixel (a set of subpixels) is formed from a combination of organic light emitting elements each emitting light of a different color, for example, a combination of one red-light emitting element, one green-light emitting element, and one blue-light emitting element.

The organic light emitting elements that form the organic light emitting device each include a pair of electrodes and an organic emission layer interposed between the pair of electrodes. The color of light emitted from the organic light emitting element can vary depending on what material is selected as a light emitting material contained in the organic emission layer.

A process that has been generally used in the production of an organic light emitting device using an organic electroluminescence (EL) element in recent years is a vacuum film formation process involving using a high-definition mask. The process includes a film formation process for an organic compound layer based on a vacuum deposition method involving using the high-definition mask and a film formation process for an upper electrode layer based on, for example, vacuum sputtering film formation involving using the mask. However, when the vacuum film formation process involving using the high-definition mask is used, the thickness of the formed organic compound layer may have a gradient owing to, for example, the alignment of the mask, the thickness of the mask, and the deflection of the mask. In this case, the thickness gradient region of the organic compound layer becomes a region that cannot be used as a constituent member for an organic light emitting element, i.e., a blurred region. Accordingly, in the vacuum film formation process involving using the high-definition mask, it has been difficult to narrow a frame region (a region outside a display area formed of a group of emission pixels, the region reaching up to a substrate end).

U.S. Pat. No. 5,953,585 describes, as a method of overcoming limits and problems occurring in the vacuum film formation process involving using the high-definition mask as described above, a method involving patterning a laminate obtained by sequentially laminating an organic compound layer, an upper electrode layer, and a protective layer by photolithography. The use of the photolithography drastically increases a definition that can be formed, and hence can suppress a blurred region that may occur in each end of a patterned organic compound layer to the minimum.

However, in the method described in U.S. Pat. No. 5,953,585, an end surface of a film serving as the organic compound layer is in a state of being exposed under an external environment after the patterning by the photolithography has been performed. In this connection, the organic compound layer has no gas barrier property, and hence when the end of the organic compound layer is exposed under the external environment, the organic compound layer itself deteriorates owing to water or oxygen that permeates from the end surface of the film. In addition, in U.S. Pat. No. 5,953,585, the patterning of the organic compound layer and the upper electrode has been performed, but U.S. Pat. No. 5,953,585 does not disclose a specific approach to electrically connecting the upper electrode and a power feeding pad portion provided on a substrate side. Accordingly, the realization of the narrowing of a frame region has involved a problem in that both the electrical connection between the upper electrode and an electrode on the substrate side, and the protection of the end of the film serving as the patterned organic compound layer against the permeation of water, oxygen, or the like need to be achieved.

### SUMMARY OF THE INVENTION

The present invention has been made to solve the problems, and an object of the present invention is to provide an organic light emitting device having a satisfactory light emitting characteristic and a narrow frame.

According to one embodiment of the present invention, there is provided an organic light emitting device, including: a substrate; and a lower electrode, an organic compound layer including an emission layer, and an upper electrode sequentially provided on the substrate, in which: the organic compound layer covers the lower electrode; the upper electrode covers the organic compound layer; the upper electrode is electrically connected to a wiring connecting portion provided in the substrate; and when an angle formed between a tilt of a section of an end in at least a partial region of the organic compound layer and a surface of the substrate is represented by θ₁, the following formulas (1) and (2) are satisfied:

tan(θ₁)=d₁/d₂ (1)

tan(θ₁)≧0.2 (2)

organic compound layer and d₂ represents a taper width of the section of the end of the organic compound layer.

According to the embodiment of the present invention, it is possible to provide the organic light emitting device having a satisfactory light emitting characteristic and a narrow frame.

Further features of the present invention will become apparent from the following description of exemplary embodiments with reference to the attached drawings.

### BRIEF DESCRIPTION OF THE DRAWINGS

FIG. 1 is a schematic sectional view for illustrating an organic light emitting device according to a first embodiment of the present invention.

FIGS. 2A, 2B, 2C, and 2D are schematic plan views for illustrating examples of the arrangement of emission pixels forming the organic light emitting device of the present invention.

FIG. 3 is a schematic sectional view for illustrating a section of an end of a film forming the organic light emitting device of FIG. 1.

FIG. 4 is a schematic sectional view for illustrating an organic light emitting device according to a second embodiment of the present invention.

FIGS. 5A, 5B, 5C, 5D, 5E, 5F, 5G, 5H, 5I, 5J, 5K, and 5L are schematic sectional views for illustrating a method of manufacturing an organic light emitting device according to Embodiment 1 of the present invention.

FIGS. 6A, 6B, 6C, 6D, 6E, 6F, 6G, 6H, 6I, 6J, 6K, 6L, 6M, 6N, and 6O are schematic sectional views for illustrating a method of manufacturing an organic light emitting device according to Embodiment 2 of the present invention.

FIGS. 7A, 7B, 7C, 7D, 7E, and 7F are schematic sectional views for illustrating a method of manufacturing an organic light emitting device according to Embodiment 3 of the present invention.

FIG. 8 is a schematic view for illustrating an example of an image forming device including the organic light emitting device according to the present invention.

FIGS. 9A and 9B are schematic plan views for illustrating specific examples of an exposure light source (exposure unit) forming the image forming device of FIG. 8, and FIG. 9C is a schematic view for illustrating a specific example of a photosensitive member forming the image forming device of FIG. 8.

FIG. 10 is a schematic view for illustrating an example of a lighting device including the organic light emitting device according to the present invention.

### DESCRIPTION OF THE EMBODIMENTS

[Organic Light Emitting Device]

Now, an organic light emitting device according to each of embodiments of the present invention is described.

### First Embodiment

An organic light emitting device according to a first embodiment of the present invention relates to an organic light emitting device including a substrate, and a lower electrode, an organic compound layer including an emission layer, and an upper electrode sequentially provided on the substrate. In the present invention, the organic compound layer covers the lower electrode, and the upper electrode covers the organic compound layer. In this embodiment, the upper electrode is electrically connected to a wiring connecting portion provided in the substrate.

In the present invention, when an angle formed between the tilt of a section of an end in at least a partial region of the organic compound layer and the surface of the substrate is represented by θ₁, the following formulas (1) and (2) are satisfied.

tan(θ₁)=d₁/d₂ (1)

tan(θ₁)≧0.2 (2)

(In the formula (1), d₁ represents a thickness of the organic compound layer and d₂ represents a taper width of the section of the end of the organic compound layer.)

It should be noted that details about the formulas (1) and (2) are described later.

Embodiments of the present invention are described in detail below with reference to the accompanying drawings as appropriate. However, the present invention is not limited to the embodiments described below.

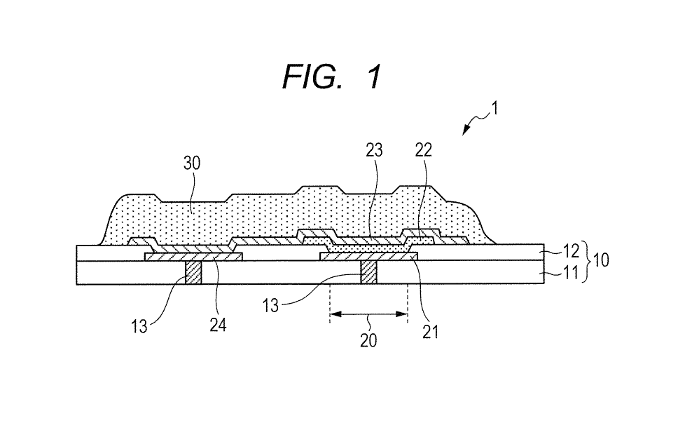

FIG. 1 is a schematic sectional view for illustrating an organic light emitting device according to a first embodiment of the present invention. An organic light emitting device 1 of FIG. 1 includes a substrate 10, which includes an interlayer insulating layer 11 and a pixel separation film 12, and an organic light emitting element in a region on the substrate 10 corresponding to an emission pixel 20. The organic light emitting element includes a lower electrode 21, an organic compound layer 22, and an upper electrode 23 in the stated order. In addition, the organic light emitting device 1 of FIG. 1 includes a wiring connecting portion 24. The wiring connecting portion 24 is an electrode member provided in the substrate 10, more specifically in a region on the interlayer insulating layer 11 forming the substrate 10 except the region corresponding to the emission pixel 20.

Though not shown in FIG. 1, the substrate 10 of the organic light emitting device 1 includes a base substrate under the interlayer insulating layer 11. In addition, drive circuits and wiring for driving the organic light emitting element may be provided between the interlayer insulating layer 11 and the base substrate in the present invention. In the case where the drive circuits and the wiring are provided between the interlayer insulating layer 11 and the base substrate, contact holes are formed in a predetermined region (for example, regions in which the lower electrode 21 and the wiring connecting portion 24 are formed) of the interlayer insulating layer 11. The contact holes 13 are filled with a conductive material for electrically connecting the electrode members (21, 24), which are formed above the interlayer insulating layer 11, to the drive circuits and the wiring.

In the organic light emitting device 1 of FIG. 1, in the pixel separation film 12, which forms the substrate 10, openings are formed in regions where the lower electrode 21 and the wiring connecting portion 24 are to be formed. The opening in the region of the pixel separation film 12 where the lower electrode 21 is to be formed is a region to serve as the emission pixel 20. The pixel separation film 12 is therefore a member that defines an emission region (an emission region defining member). In the present invention, the shape in plan view of the emission region 20 may be defined by a method involving forming the pixel separation film 12 above the lower electrode 21 through patterning in a predetermined shape, and may be defined by patterning the lower electrode 21 in advance through photolithography or the like.

In the organic light emitting device 1 of FIG. 1, the lower electrode 21, which forms the organic light emitting element, is an electrode formed on the interlayer insulating layer 11, which forms the substrate 10, and the ends of the lower electrode 21 are covered with the pixel separation film 12.

In the organic light emitting device 1 of FIG. 1, the organic compound layer 22, which forms the organic light emitting element, is a member formed selectively in the emission region 20 and a region surrounding the emission region 20. The organic compound layer 22 in the present invention is formed through patterning with the use of a predetermined photomask. It should be noted that a specific method for this patterning is described later together with details about the organic compound layer 22 (constituent materials, a film formation method, and the like).

In the organic light emitting device 1 of FIG. 1, the upper electrode 23 formed on the organic compound layer is electrically connected to the wiring connecting portion 24 (pad portion). It should be noted that the ends of the wiring connecting portion 24 are covered with the pixel separation film 12.

A sealing layer 30 is formed in the organic light emitting device 1 of FIG. 1 for the purpose of covering and protecting at least the organic compound layer. In the present invention, however, a protective member for protecting the organic light emitting element is not limited to the sealing layer 30 in FIG. 1. It should be noted that the emission pixel 20 and the wiring connecting portion 24 are formed within the sealing layer 30 as illustrated in FIG. 1.

Though not shown in FIG. 1, an external connection terminal portion is arranged outside the sealing layer 30. An external connection terminal is a terminal for supplying external signals and power supply voltage to a circuit (not shown). It is preferred for the sealing layer 30 in the present invention to be patterned so as to have an opening in a region where the external connection terminal portion is to be provided, which is formed on a first principal surface side of the substrate 10.

An organic light emitting device of the present invention includes at least one organic light emitting element formed on a substrate. In the case where the organic light emitting device includes two or more organic light emitting elements, the organic light emitting elements may emit light of the same color or different colors from one another. In addition, in the case where the organic light emitting device includes two or more organic light emitting elements, the organic light emitting device may arrange the two or more organic light emitting elements so that, for example, pixels each of which is a combination of a plurality of organic light emitting elements are arranged in lines or in a matrix, but the present invention is not limited to this arrangement mode. The organic light emitting device of the present invention may use the upper electrode 23 or the lower electrode 21 as an electrode from which light emitted from an emission layer, which forms the organic compound layer 22, is extracted. The mode of extracting light emitted from the emission layer is not limited to an “either-or” mode in which the emitted light is extracted from the upper electrode 23 or the lower electrode 21, and may be a mode in which the emitted light is extracted from both the electrodes (21, 23). When the electrode from which light emitted from the emission layer is extracted is a semi-transmissive or transparent electrode, the light can be extracted from the interior of the organic light emitting element that forms the organic light emitting device.

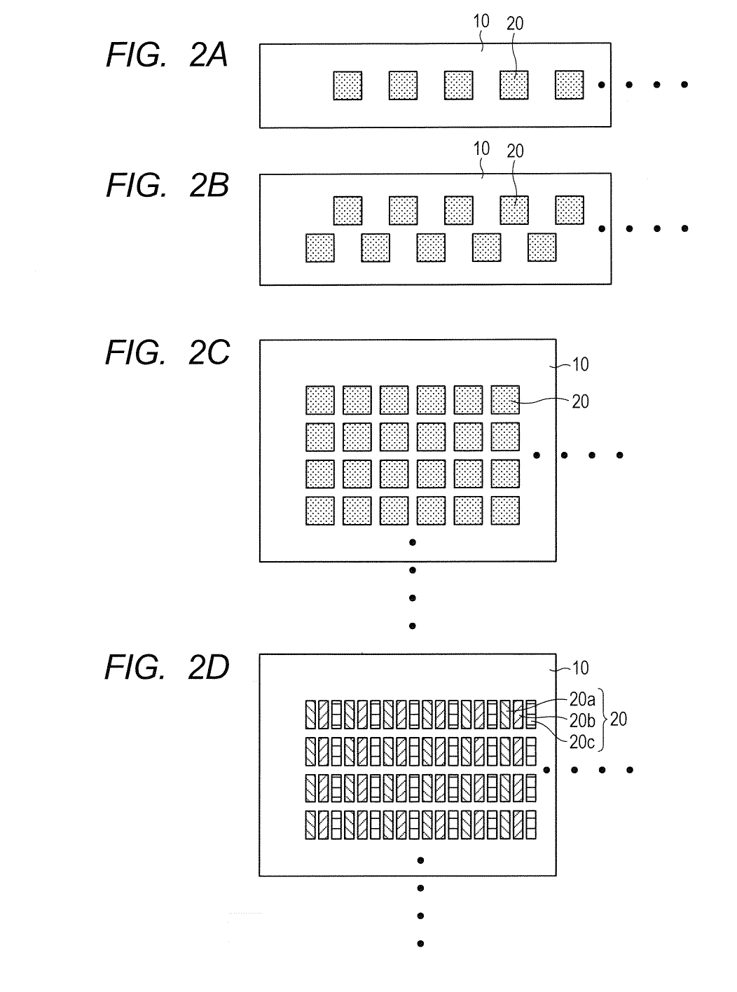

FIGS. 2A to 2D are schematic plan views for illustrating arrangement examples of emission pixels that form the organic light emitting device of the present invention. The emission pixels 20 in the present invention can be arranged in lines (FIG. 2A), in staggered lines (FIG. 2B), in a two-dimensional matrix (FIG. 2C or FIG. 2D), and the like, but are not limited to those arrangement examples. In the case where the organic light emitting device of the present invention is used as a linear light source for a print head, it is preferred to arrange the emission pixels 20 in lines (FIG. 2A) or in staggered lines (FIG. 2B). In the case where the organic light emitting device of the present invention is used as a display, a two-dimensional matrix arrangement (FIG. 2C or FIG. 2D) can be employed. In the form of FIG. 2D in which each emission pixel 20 includes a plurality of types of subpixels (20a, 20b, 20c), in particular, images can be displayed in full color by selecting an appropriate light emitting material for each different type of subpixel.

Now, the reason why the layout margin of the organic compound layer 22 or the upper electrode 23 can be reduced is described.

First, a thin film serving as the organic compound layer 22 or upper electrode 23 forming the organic light emitting device is described. In the present invention, when an angle formed between the tilt of a section of an end of the organic compound layer 22 and the surface of the substrate 10 is represented by θ₁, the following formulas (1) and (2) are satisfied.

tan(θ₁)=d₁/d₂ (1)

tan(θ₁)≧0.2 (2)

In the formula (1), d₁ represents a thickness of the organic compound layer 22. In addition, in the formula (1), d₂ represents a taper width of the section of the end of the organic compound layer 22.

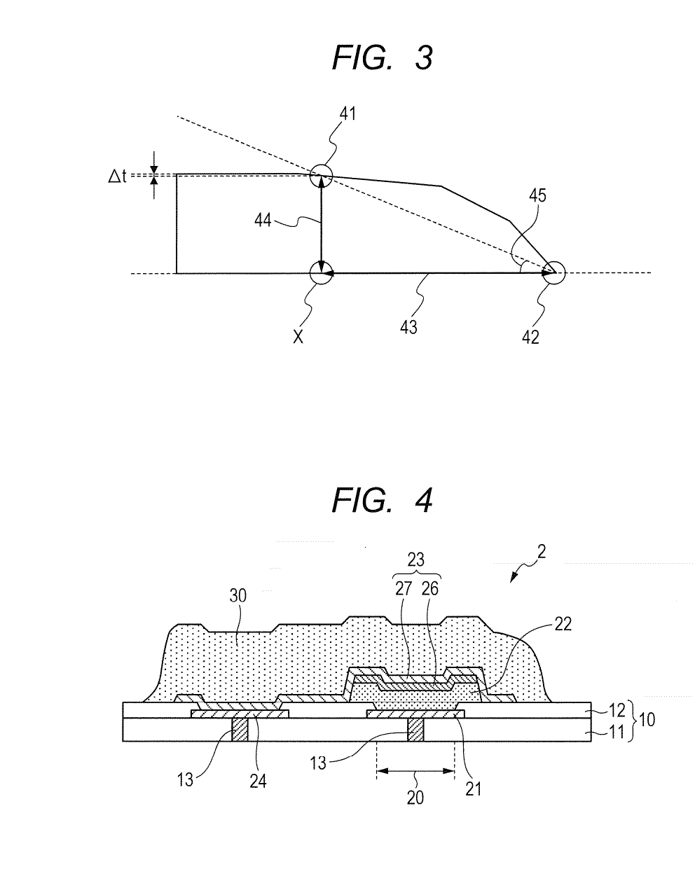

FIG. 3 is a schematic sectional view for illustrating the section of an end of a film that forms the organic light emitting device of FIG. 1. It should be noted that FIG. 3 is also a diagram for illustrating the shape of a thickness gradient region in predetermined films. In addition, the film illustrated in FIG. 3 is a film to serve as the organic compound layer 22 or the upper electrode 23.

As illustrated in FIG. 3, an end of the film to serve as the organic compound layer 22 or the upper electrode 23 is thinner than other portions of the film such as the central portion. The region where the film is thinner than other portions illustrated in FIG. 3 is a region called a thickness gradient region. Taking a film to serve as the organic compound layer 22 as an example, a thickness gradient region in the organic compound layer is formed between an edge of the substrate 10 and the emission region defining unit, which is at the outermost perimeter of a display region (the emission region 20), in particular, at an end of the film to serve as the organic compound layer 22.

A portion of a predetermined film that is thinner than a film forming error (−Δt) of the film is denoted by reference symbol 41, and a portion of the film that has a thickness of 0 nm is denoted by reference symbol 42. The distance from the point denoted by reference symbol 42 to a point where a vertical line drawn down from the point denoted by reference symbol 41 meets the substrate (a point X), namely, a distance denoted by reference symbol 43, is defined as a film end taper width of the predetermined film. It should be noted that in the case where the predetermined film is the organic compound layer 22, the distance denoted by reference symbol 43 is d₂ in the formula (1). Meanwhile, the thickness of the film at the point denoted by reference symbol 41 corresponds to the distance between the point denoted by reference symbol 41 and the point X that is denoted by reference symbol 44. In the case where the predetermined film is the organic compound layer 22, the distance denoted by reference symbol 44 is d₁ in the formula (1). An angle formed between a tilt of the section of the film end and the substrate surface in FIG. 3 is denoted by reference symbol 45, and is θ₁ in the formulas (1) and (2).

In the present invention, a value of tan(θ₁), which is determined by the formula (1) from d₁ and d₂, is 0.2 or more. Thus, the thickness gradient region, which is generated at an end of a film to serve as the organic compound layer 22, can be reduced in size. In addition, the reduction in size of the thickness gradient region can reduce a frame region (a region outside the display region, which is formed from a group of emission pixels, the region extending from the display region to the substrate edges) in size in the organic light emitting device. For example, such design that a distance between the wiring connecting portion and the pixel is reduced can be achieved, which leads to the narrowing of the frame region.

In addition, in the present invention, it is preferred that when an angle formed between the tilt of the section of an end of the upper electrode 23 and the surface of the substrate is represented by θ₂, the following formulas (3) and (4) be satisfied.

tan(θ₂)=d₃/d₄ (3)

tan(θ₂)≧0.2 (4)

In the formula (3), d₃ represents a thickness of the upper electrode. In addition, in the formula (3), d₄ represents a taper width of the section of the end of the upper electrode.

The value of tan(θ₂), which is determined by the formula (3) from d₃ and d₄, is 0.2 or more. Thus, the thickness gradient region, which is generated at an end of a film to serve as the upper electrode 23, can be reduced in size as in the case of the organic compound layer 22, and the frame region can be further narrowed.

As described above, when the shape of an end of a film forming a predetermined layer (22, 23) is controlled, in a light emitting device whose frame region is defined by film forming ends of at least the organic compound layer 22 and the upper electrode 23, the frame region can be narrowed. The narrowing of the frame region also increases the number of organic light emitting devices that can be taken from a single sheet of mother glass, which leads to an improvement in productivity.

In addition, in the organic light emitting device 1 of FIG. 1, an end of the organic compound layer 22 is covered with the upper electrode 23. Accordingly, the penetration of water or oxygen from the end of the film to serve as the organic compound layer 22 can be suppressed, and hence the deterioration of the organic compound layer 22 due to the permeation of water, oxygen, or the like in a lateral direction of the film (direction parallel to the substrate surface) can be alleviated.

Further, in the organic light emitting device of the present invention, it is preferred for the section of an end of the film serving as the organic compound layer 22 to have a taper width of 5 μm or less, more preferably 1 μm or less.

It should be noted that the shapes of the ends of the film serving as the organic compound layer 22 may be identical to or different from each other in tan θ as long as the shapes each have a tan θ of 0.2 or more. In addition, each end of the film serving as the organic compound layer 22 is covered with the upper electrode 23, and hence the penetration of water or oxygen from the end of the film can be suppressed. In addition, the upper electrode 23 is covered with the sealing layer 30, and hence the penetration of water or oxygen from the end of the film can be suppressed in an additionally effective manner.

### Second Embodiment

Now, an organic light emitting device according to a second embodiment of the present invention is described. It should be noted that in the following description, a difference from the first embodiment is mainly described.

The organic light emitting device according to this embodiment is identical to the organic light emitting device according to the first embodiment except that the upper electrode has a first upper electrode layer and a second upper electrode layer in the stated order particularly in the region where the emission pixel is arranged. In this embodiment, the planar pattern of the organic compound layer is substantially identical to the planar pattern of the first upper electrode layer, and at least a part of the second upper electrode layer overlaps the first upper electrode layer. In this embodiment, the second upper electrode layer is electrically connected to the wiring connecting portion provided in the substrate in a region where the second upper electrode layer does not overlap the first upper electrode layer.

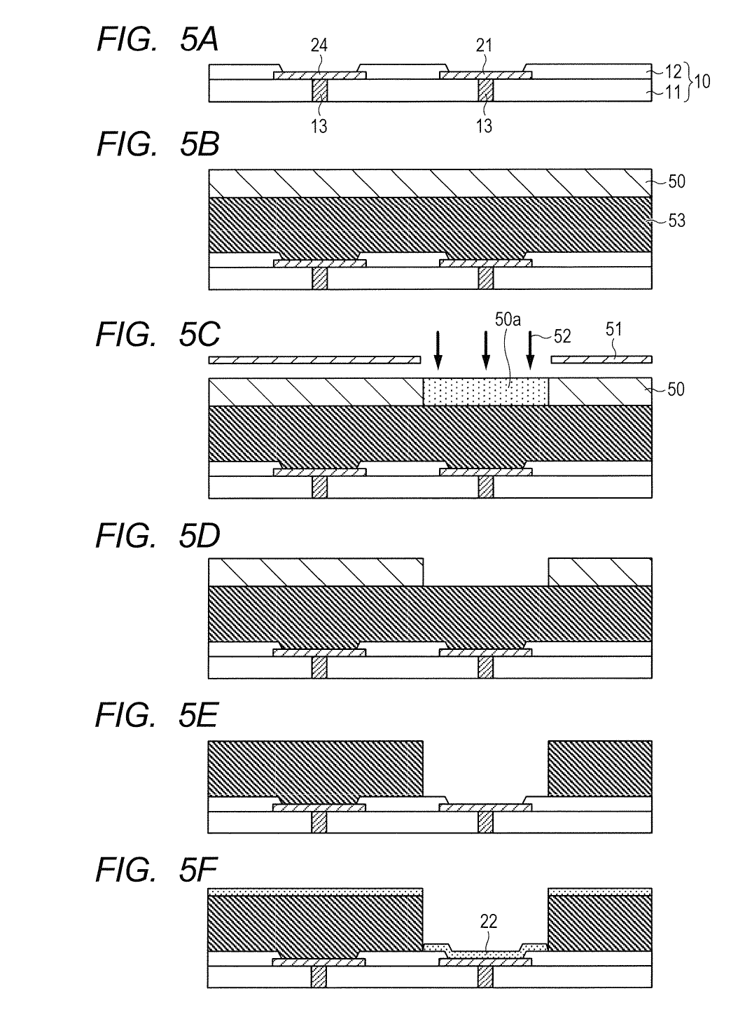

FIG. 4 is a schematic sectional view for illustrating an organic light emitting device according to a second embodiment of the present invention. An organic light emitting device 2 of FIG. 4 includes the substrate 10, which includes the interlayer insulating layer 11 and the pixel separation film 12, and an organic light emitting element arranged in a region on the substrate 10 corresponding to the emission pixel 20. The organic light emitting element includes the lower electrode 21, the organic compound layer 22, a first upper electrode layer 26, and a second upper electrode layer 27. It should be noted that in the organic light emitting device 2 of FIG. 4, the upper electrode 23 is an electrode obtained by laminating the first upper electrode layer 26 and the second upper electrode layer 27 in the stated order. In addition, the organic light emitting device 2 of FIG. 4 has the wiring connecting portion 24. The wiring connecting portion 24 is an electrode member provided in the substrate 10, more specifically in a region on the interlayer insulating layer 11 forming the substrate 10 except the region corresponding to the emission pixel 20.

In the organic light emitting device 2 of FIG. 4, the organic compound layer 22 and first upper electrode layer 26 forming the organic light emitting element are members selectively provided in the emission region 20 and a region around the region. In the present invention, the organic compound layer 22 and the first upper electrode layer 26 are formed by utilizing patterning involving using the same photomask, and hence the planar shapes (planar patterns) of both the members are substantially identical to each other. It should be noted that a specific method for the patterning is described later together with details about the organic compound layer 22 and the first upper electrode layer 26 (such as a constituent material and a film formation method).

In this embodiment, it is preferred that an angle formed between the tilt of the section of an end of the first upper electrode layer 26 and the surface of the substrate is represented by θ₃, the following formulas (5) and (6) be satisfied.

tan(θ₃)=d₅/d₆ (5)

tan(θ₃)≧0.2 (6)

In the formula (5), d₅ represents a thickness of the first upper electrode layer and d₆ represents a taper width of the section of the end of the first upper electrode layer.

When a value of tan(θ₃), which is determined by the formula (5) from d₅ and d₆, is 0.2 or more, the thickness gradient region, which is generated at an end of a film to serve as the first upper electrode layer 26, can be reduced in size as in the case of the organic compound layer 22.

Further, in this embodiment, it is more preferred that when an angle formed between the tilt of the section of an end of the second upper electrode layer 27 and the surface of the substrate is represented by θ₄, the following formulas (7) and (8) be satisfied.

tan(θ₄)=d₇/d₈ (7)

tan(θ₄)≧0.2 (8)

(In the formula (7), d₃ represents a thickness of the second upper electrode layer and d₄ represents a taper width of the section of the end of the first upper electrode layer.)

When a value of tan(θ₄), which is determined by the formula (7) from d₇ and d₈, is 0.2 or more, at least the thickness gradient region, which is generated at an end of the upper electrode layer 27 arranged between the end of the substrate and the emission region defining unit at the outermost peripheral portion of the display region, can be reduced in size.

As described above, in the planar patterns of the organic compound layer 22 and the first upper electrode layer 26 or the second upper electrode layer 27, the shape of an end is preferably controlled so that the tan(θ) value of at least one side on a substrate plane may be 0.2 or more. It is more preferred that tan(θ) values in all sides be 0.2 or more.

As described above, in this embodiment, when the shape of an end of a film forming the predetermined layer (22, 26, 27) is controlled, in a light emitting device whose frame region is defined by film forming ends of at least the organic compound layer 22 and the upper electrode 23, the frame region can be narrowed. The narrowing of the frame region also increases the number of organic light emitting devices that can be taken from a single sheet of mother glass, which leads to an improvement in productivity.

In addition, in the organic light emitting device 2 of FIG. 4, an end of the organic compound layer 22 is covered with the upper electrode 23, more specifically the first upper electrode layer 26 and second upper electrode layer 27 forming the upper electrode 23. Accordingly, the penetration of water or oxygen from the end of the film serving as the organic compound layer 22 can be suppressed, and hence the deterioration of the organic compound layer 22 due to the permeation of water, oxygen, or the like in a lateral direction of the film (direction parallel to the substrate surface) can be alleviated.

In the present invention, the second upper electrode layer 27 preferably covers the first upper electrode layer 26 as illustrated in FIG. 4. This is because of the following reason: when a physical through-hole or gap such as a pinhole or a crack opens in the first upper electrode layer 26, the physical through-hole or gap can be covered with the second upper electrode layer 27. In addition, when patterning is performed so that a pattern end of the second upper electrode layer 27 may be superimposed on the pattern of the first upper electrode layer 26, the first upper electrode layer 26 directly serves as an etching stopper to be over-etched, and hence the thickness of the first upper electrode layer 26 may partially change and the organic compound layer 22 may receive some damage. However, the change in thickness does not cause any particular problem unless a region that is over-etched and a region that is not over-etched are mixed in the emission pixel 20. Accordingly, the second upper electrode layer 27 is preferably arranged in, for example, a region wider than the first upper electrode layer 26, i.e., so as to cover the first upper electrode layer 26 as illustrated in FIG. 4.

[Method of Manufacturing Organic Light Emitting Device]

Next, a method of manufacturing an organic light emitting device of the present invention is described.

### Embodiment 1

Now, a method of manufacturing an organic light emitting device according to Embodiment 1 of the present invention is described. The method of manufacturing an organic light emitting device of the present invention includes the following manufacturing processes:

(A) a step of providing an emission defining region for determining an emission region on a lower electrode;
(B) a step of forming an organic compound layer on the lower electrode;
(C) a step of patterning an end of the organic compound layer; and
(D) a step of forming an upper electrode on the organic compound layer.

In addition, in this embodiment, the step of forming the upper electrode (step (D)) is preferably a step of arranging the upper electrode so that the electrode may be connected to a pad portion that electrically communicates with a wiring connecting portion, covers an end of the organic compound layer, and is provided on a substrate so as to establish electrical communication on a substrate side.

Now, details about the respective processes of this embodiment are described. In this embodiment, the step of patterning the organic compound layer includes the following steps:

(C1) a step of forming a lift-off layer before the step of forming the organic compound layer;
(C2) a step of patterning the lift-off layer through the use of photolithography in such a manner that at least the lift-off layer formed in a region where the pad portion is arranged remains; and
(C3) a step of removing the lift-off layer together with the organic compound layer provided on the lift-off layer after the step of forming the organic compound layer.

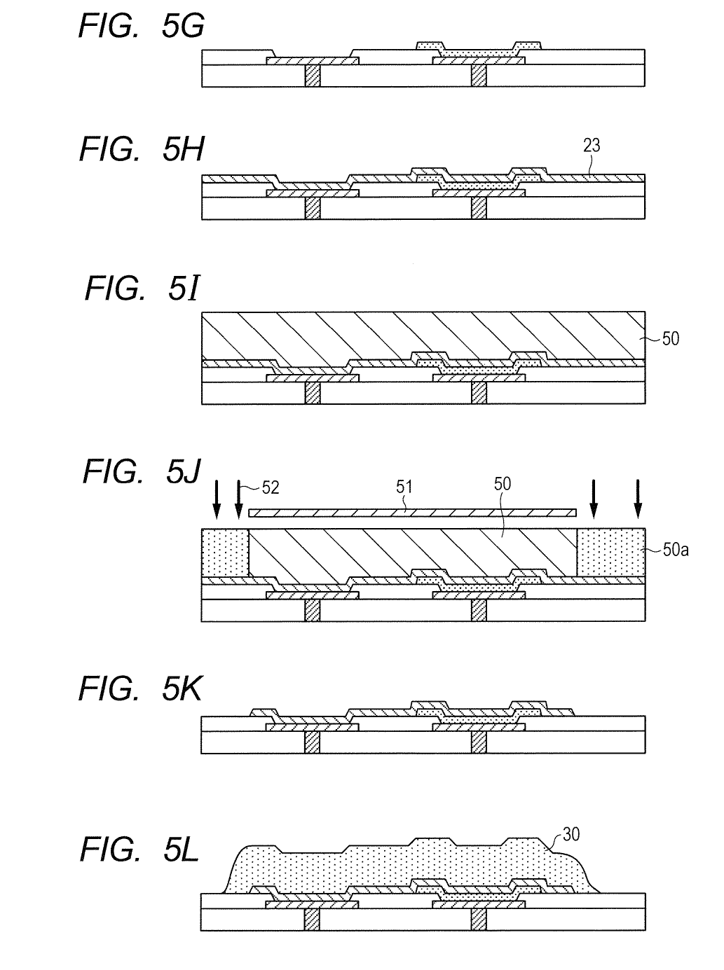

FIGS. 5A to 5L are schematic sectional views for illustrating a method of manufacturing an organic light emitting device according to Embodiment 1 of the present invention. It should be noted that the manufacturing process illustrated in FIGS. 5A to 5L is also a manufacturing process for the organic light emitting device 1 of FIG. 1.

(1-1) Substrate Forming Step (FIG. 5A)

A substrate that is used to manufacture an organic light emitting device is manufactured first (FIG. 5A). The substrate 10 to be used in this embodiment (Embodiment 1) includes at least the interlayer insulating layer 11 and the pixel separation film 12. In the substrate 10 illustrated in FIG. 5A, the lower electrode 21 and the wiring connecting portion 24 are formed on the interlayer insulating layer 11 in predetermined locations/regions, and ends of the lower electrode 21 and the wiring connecting portion 24 are covered with the pixel separation film 12. The pixel separation film 12 has an opening 12a in a region corresponding to the emission pixel 20, and an opening 12a at a contact position where the wiring connecting portion 24 comes into contact with the upper electrode. It should be noted that though not shown in FIG. 5A, the substrate 10 may include a control circuit for controlling the driving of the organic light emitting device. In the case where the control circuit is included in the substrate 10, the contact holes 13 are formed in part of the interlayer insulating layer 11 for the purpose of securing electrical connection between the control circuit and the lower electrode 21 or the wiring connecting portion 24.

A constituent material for the interlayer insulating layer 11, which forms the substrate 10 illustrated in FIG. 5A, is not particularly limited, but a material containing silicon nitride (SiN) or silicon oxide (SiO), which is excellent in insulating property, is preferred. In addition, in the present invention, the term “SiN” does not mean a composition ratio of 1:1 and its meaning is not limited to a composition ratio.

A constituent material for the lower electrode 21, which is provided on the interlayer insulating layer 11, is appropriately selected depending on the function of the lower electrode 21 for light emitted from the emission layer (whether the lower electrode 21 transmits the light or reflects the light). In the case where the lower electrode 21 is to reflect the light emitted from the emission layer, an electrode layer having light reflectivity is used for the lower electrode 21. An example of the constituent material for the lower electrode in this case is a metal material having high light reflectivity, such as aluminum (Al) or silver (Ag). However, the structure of the lower electrode 21 in this case is not limited to a single layer of the metal material having light reflectivity described above. A laminated electrode film that includes a layer of a metal material having light reflectivity and a layer of a transparent conductive material such as ITO or indium zinc oxide may also be employed as the lower electrode 21. In the case where the lower electrode 21 is to transmit the light emitted from the emission layer, an electrode layer having a light transmission property is used for the lower electrode 21. An example of the constituent material for the lower electrode 21 in this case is a transparent conductive material such as ITO or indium zinc oxide.

In the case where the lower electrode 21 and the wiring connecting portion 24 are formed simultaneously, a constituent material for the wiring connecting portion 24 is the same as that for the lower electrode 21. Meanwhile, the lower electrode 21 and the wiring connecting portion 24 in the present invention can be formed by separate processes. The constituent material for the wiring connecting portion 24 in this case may differ from the constituent material for the lower electrode 21.

The contact holes 13 formed in predetermined regions of the interlayer insulating layer 11 are each filled with a connection wiring member for electrically connecting wiring or the circuit (not shown), which is below the interlayer insulating layer 11, to the lower electrode 21 or the wiring connecting portion 24. The connection wiring member can be a highly conductive material but is not particularly limited in the present invention.

A constituent material for the pixel separation film 12 is not particularly limited as long as the material is an insulative material. In the case of organics, however, a material containing polyimide as a main component is preferred, and in the case of inorganics, silicon nitride (SiN), silicon oxide (SiO), or the like is preferred.

(1-2) Steps of Forming Lift-Off Layer and Photoresist (FIG. 5B)

Next, a lift-off layer 53 is formed over the entire surface of the substrate 10. A material to be used in the formation of the lift-off layer 53 is a material having solubility in a solvent that does not dissolve the organic compound layer 22, and is preferably, for example, a water-soluble polymer material. When a water-soluble polymer is used as a constituent material for the lift-off layer 53, an application system such as spin coating or dip coating is adopted as a method of forming the lift-off layer 53, and the layer can be easily formed.

Further, a resist layer 50 containing a photosensitive material is formed on the lift-off layer 53 (FIG. 5B). The resist layer 50 is formed by a wet film formation method such as an application method, but a solvent to be used in the formation of the layer is not particularly limited as long as the solvent does not dissolve the lower layer (lift-off layer 53). It should be noted that when the lift-off layer 53 may be corroded by the solvent to be used in the formation of the resist layer 50, a protective layer (not shown) formed of an inorganic compound such as silicon nitride or silicon oxide may be inserted between the lift-off layer 53 and the resist layer 50. In addition, in this embodiment, a photolithography process involving using a positive photoresist is adopted, but a photolithography process involving using a negative photoresist is also permitted.

(1-3) Exposing Step (FIG. 5C)

Next, the resist layer 50 and the lift-off layer 53 are selectively removed from a region where the patterned organic compound layer 22 is to be provided (region where the emission pixel 20 is to be provided). For example, when the resist layer 50 is a positive resist, as illustrated in FIG. 5C, a resist layer 50a exposed so as to surround at least the emission pixel 20 is formed by exposing the region where the organic compound layer 22 is to be arranged to light 52 through a mask 51 having an opening. On the other hand, when the resist layer 50 is formed of a negative resist, the exposed resist layer 50a of the same shape can be formed by using a mask having a reversed opening pattern.

(1-4) Step of Processing Lift-Off Layer (FIGS. 5D and 5E)

Next, after the exposed resist layer 50a has been removed by development with a developer, dry etching is performed by using the patterned resist layer 50 as a mask. A specific method for the dry etching is not particularly limited as long as a gas that can etch the lift-off layer 53 is used. In this embodiment, an oxygen gas is used as the gas for etching the lift-off layer 53 (etching gas), but the gas is not limited thereto. When the processing of the lift-off layer 53 by the dry etching is completed, part or the entirety of the resist layer 50 used as an etching mask is removed by the dry etching. Illustrated in FIG. 5E is a situation in which the resist layer 50 is removed by the dry etching when the processing of the lift-off layer 53 by the dry etching is completed. In this step, however, there is no need to remove the resist layer 50. In the case where the thickness of the gas species or the lift-off layer is much smaller than that of the resist layer 50, the photoresist as a constituent material for the resist layer 50 may remain. In this case, however, the remaining resist layer 50 may be removed by using a peeling liquid or the like, or the resist layer 50 may be removed by further performing the dry etching. Alternatively, the resist layer 50 may be left as it is. It should be noted that the resist layer 50 provided on the lift-off layer 53 is preferably formed so as to have a proper thickness because the resist layer 50 can also be removed at the time of the dry etching of the lift-off layer 53. In addition, the lower electrode 21 is exposed by this step (FIG. 5E). In this case, a pretreatment is desirably performed before a film serving as the organic compound layer 22 is formed in the next step. For example, the charge injection property of the lower electrode 21 is adjusted, and a contaminant or the like that may occur on the lower electrode 21 is removed, by subjecting the substrate 10 to an argon plasma treatment, an oxygen plasma treatment, a UV irradiation treatment, or a heat treatment.

(1-5) Step of Forming Organic Compound Layer (FIG. 5F)

Next, the film serving as the organic compound layer is formed on the lower electrode 21 (FIG. 5F). The organic compound layer 22 to be formed on the lower electrode 21 and the like in this step is a laminate formed of one or more layers including at least an emission layer. When the organic compound layer 22 is formed of a plurality of layers, a layer except the emission layer is specifically, for example, a hole injection layer, a hole transport layer, an electron blocking layer, a hole blocking layer, an electron transport layer, or an electron injection layer. In addition, the layer construction of the organic compound layer 22 is not particularly limited, though the layer construction varies depending on the characteristics of the upper electrode 23 to be formed in a subsequent step. The term “characteristics of the upper electrode 23” as used herein mainly refers to a carrier to be injected from the upper electrode 23. When the upper electrode 23 injects a hole (positively charged carrier), a layer between the lower electrode 21 and the emission layer is a layer for injecting and transporting an electron, and a layer between the upper electrode 23 and the emission layer is a layer for injecting and transporting a hole. When the upper electrode 23 injects an electron (negatively charged carrier), the layer between the lower electrode 21 and the emission layer is a layer for injecting and transporting a hole, and the layer between the upper electrode 23 and the emission layer is a layer for injecting and transporting an electron.

Available as a method of forming the organic compound layer 22 is an application system such as spin coating or a film formation method based on a vacuum deposition method or the like. The layer is often formed by the vacuum deposition method from the viewpoint of element performance, but in the present invention, the film formation system is not particularly limited.

Each of the layers forming the organic compound layer 22 is described. The hole injection layer is formed between the hole transport layer and an electrode for injecting holes (an anode) to improve a hole injection property and thereby contribute to make the organic light emitting element that forms the organic light emitting device low in voltage and long in life. The hole injection layer in the present invention is also a layer containing an organic compound that has an electron-withdrawing substituent. Further, in the present invention, it is preferred for at least one of the layers forming the organic compound layer 22 to function as a layer that covers an end of the hole injection layer to protect the hole injection layer.

The hole transport layer is a layer made of a material that has a main function of transporting holes.

The electron blocking layer is formed between the emission layer and the hole transport layer and has a function of blocking the leakage of electrons from the emission layer to the anode side to confine electrons within the emission layer. The electron blocking layer is a layer for increasing the efficiency of the organic light emitting element that forms the organic light emitting device.

The emission layer is a layer mainly for obtaining light emission through the recombination of holes and electrons, and is made generally from two types of materials called a host and a guest. The guest is a light emitting material and the content (weight ratio) of the guest in relation to the entire emission layer is about 10% or less. It should be noted that the emission layer may contain an additional material in addition to the host and the guest from the viewpoint of element characteristics.

The hole blocking layer is formed between the electron transport layer and the emission layer, and has a function of blocking the leakage of holes from the emission layer to the cathode side to confine holes in the emission layer. The hole blocking layer is a layer for increasing the efficiency of the organic light emitting element that forms the organic light emitting device.

The electron transport layer is a layer mainly for transporting electrons.

The electron injection layer is formed between the electron transport layer and an electrode for injecting electrons (a cathode) to mainly improve an electron injection property and thereby contribute to make the organic light emitting element that forms the organic light emitting device low in voltage and long in life.

It should be noted that the lack of or the duplication of any layer in the laminated structure described above does not affect the end structure of the resultant film, which serves as the organic compound layer 22. Consequently, the effects of the present invention are not influenced by the specifics of the laminated structure of the organic compound layer. In addition, the order in which the layers forming the organic compound layer 22 are laminated is determined by whether the lower electrode 21 is an anode or a cathode, but is not limited in the present invention.

In this embodiment, at least water and other are used to perform lift-off in a lift-off step to be described later. Preferred constituent materials for the layers that form the organic compound layer 22 are therefore materials that are insoluble in at least water. In particular, an alkali metal or an alkaline earth metal is generally used for the electron injection layer from the viewpoint of an electron injection property. However, the alkali metal and the alkaline earth metal may react with water upon contact and dissolve. Therefore, an electron injecting material having low water solubility, such as an organic metal complex, is used as a constituent material for the electron injection layer. The phrase “low water solubility” as used herein means that a reduction in thickness of a thin film due to dissolution does not occur even when the film is brought into contact with water for 1 minute after the formation of the film. It should be noted that the electron injection layer may be a layer obtained by mixing the electron injection material and another material such as an electron transport material from the viewpoint of reducing the water solubility. In addition, the electron injection layer may be a single layer or a laminate including a plurality of layers.

(1-6) Lift-Off Step (FIG. 5G)

Next, lift-off is performed to remove the lift-off layer 53 and the organic compound layer 22 present on the layer (FIG. 5G). Water having a small solubility for an organic material is preferably used at the time of the lift-off. With regard to a method for the lift-off, the layers may be immersed in water or may be further irradiated with an ultrasonic wave, or water may be blown onto the substrate 10 with a two-fluid nozzle. After the lift-off step, the organic compound layer 22 is patterned into a shape surrounding the emission pixel 20. In addition, the wiring connecting portion 24 is exposed at the time of the lift-off. It should be noted that after the lift-off step has been performed, the step of baking the substrate 10 in a vacuum to remove a residual component that may be caused by the lift-off step involving using water or the like from the insides of the substrate 10 and the organic compound layer 22 is preferably added as an additional step for obtaining additionally excellent element characteristics.

(1-7) Step of Forming Upper Electrode (FIG. 5H)

After the processing of the organic compound layer 22, the upper electrode 23 is formed on the organic compound layer 22 (FIG. 5H). Here, the upper electrode 23 is formed over the entire surface of the substrate 10 as illustrated in FIG. 5H. Accordingly, an end of the organic compound layer 22 is covered with the upper electrode 23. Accordingly, in the present invention, high durability can be obtained because the present invention corresponds to the case where the tan(θ) (tan(θ₁)) described with reference to FIG. 3 serving as an indicator of the shape of the end of the organic compound layer 22 is 0.20 or more.

A constituent material for the upper electrode 23 is appropriately selected depending on the function of the upper electrode 23 for light emitted from the emission layer (whether the upper electrode 23 transmits the light or reflects the light). In the case where the upper electrode 23 is to reflect the light emitted from the emission layer, an electrode layer having light reflectivity is used for the upper electrode 23. An example of the constituent material for the upper electrode in this case is a metal material having high light reflectivity, such as aluminum (Al) or silver (Ag). However, the structure of the upper electrode 23 in this case is not limited to a single layer of the metal material having light reflectivity described above. A laminated electrode film that includes a layer of a metal material having light reflectivity and a layer of a transparent conductive material such as ITO or indium zinc oxide may also be employed as the upper electrode 23. In the case where the upper electrode 23 is to transmit the light emitted from the emission layer, an electrode layer having a light transmission property is used for the upper electrode 23. An example of the constituent material for the upper electrode 23 in this case is a transparent conductive material such as ITO or indium zinc oxide. Layers made of those materials are known to be much denser than the organic compound layer 22 and accordingly low in gas permeability. Covering an end of the organic compound layer 22 with the upper electrode 23 at the time the upper electrode 23 is formed therefore protects the organic compound layer 22 under the upper electrode 23 from the permeation of water or a gas such as oxygen.

(1-8) Step of Patterning Upper Electrode (FIG. 5I to FIG. 5K)

In the present invention, the tan(θ) (tan(θ₂)) described with reference to FIG. 3 serving as an indicator of a sectional shape of an end of an electrode film serving as the upper electrode 23 is preferably 0.20 or more. Setting the tan(θ₂) to 0.20 or more can reduce the thickness gradient region of the upper electrode 23. In order to obtain an end surface having a tan(θ₂) of 0.20 or more, the electrode film serving as the upper electrode 23 is formed, and then the electrode film is processed (patterned) into a predetermined shape. First, the resist layer 50 is formed on the upper electrode 23 (FIG. 5I). When the photoresist to be used in the formation of the resist layer 50 is a positive resist, the exposure light 52 is applied toward the substrate 10 by using the photomask having an opening in a region from which the upper electrode 23 is to be removed as illustrated in FIG. 5J. Thus, the exposed resist layer 50a is obtained. When the resist layer 50 is formed by using a negative resist, the exposed resist layer 50a of the same shape as that described above is obtained by performing exposure with a photomask having a reversed pattern.

The exposed resist layer 50a is removed by development, and then the upper electrode 23 in a portion that is not covered with the resist layer 50 is removed. Wet etching or dry etching can be used as a method for the removal, but the dry etching that does not involve using a solvent or the like is preferred because the wet etching is liable to cause a failure such as film peeling. When the upper electrode 23 is processed by the dry etching, the electrode can be processed by performing, for example, plasma etching involving using a chlorine gas or an argon gas because the dry etching is the dry etching of a metal material.

As described above, the tan(θ₂) serving as an indicator of the shape of an end of the electrode film serving as the upper electrode 23 is set to 0.20 or more by processing the upper electrode 23. Thus, the upper electrode 23 formed by, for example, a sputtering method or an EB deposition method can be formed in such a manner that its frame region is reduced.

(1-9) Sealing Step (FIG. 5L)

After the upper electrode 23 has been formed, the organic light emitting element and wiring connecting portion 24 forming the organic light emitting device may be sealed with a glass cap or the like, or may be sealed with a sealing thin film formed of an inorganic material. The organic light emitting element and the wiring connecting portion 24 are preferably sealed with the sealing thin film formed of an inorganic material. In this embodiment, the sealing layer 30 (sealing thin film) is formed on the upper electrode 23 (FIG. 5L). Available as a constituent material for the sealing layer 30 is an inorganic material having a high moisture barrier property such as silicon nitride, silicon oxide (SiO), or aluminum oxide (AlO). In the present invention, however, it is sufficient that the sealing with the thin film can be performed, and the material itself and its composition ratio are not particularly limited.

In addition, in the present invention, after the sealing layer 30 has been formed, the sealing layer 30 may be patterned for the purpose of, for example, exposing an electrode pad for external connection (external connection terminal) for connection to an external circuit. In addition, in the present invention, all ends of the upper electrode 23 are preferably covered with the sealing layer 30. Thus, the permeation of a component such as water or oxygen from an end surface of the upper electrode 23 can be additionally prevented, and hence the following effect can be expected: the durability of the element forming the organic light emitting device further improves.

### Embodiment 2

Next, a method of manufacturing an organic light emitting device according to Embodiment 2 of the present invention is described. It should be noted that in this embodiment, for example, the organic light emitting device of FIG. 4 can be manufactured. The method of manufacturing an organic light emitting device according to Embodiment 2 of the present invention includes the following production processes:

(A) a step of forming an emission defining member for determining an emission region on a lower electrode;
(B) a step of continuously forming an organic compound layer and a first upper electrode layer on the lower electrode;
(C) a step of patterning an organic compound layer and the first upper electrode layer in the same planar pattern; and
(D) a step of forming a second upper electrode layer on the first upper electrode layer.

Now, differences from the method of manufacturing the organic light emitting device 2 are described.

It should be noted that in the step (D), at least a part of the second upper electrode layer overlaps the first upper electrode layer, and the second upper electrode layer is electrically connected to a wiring connecting portion provided in a substrate in a region where the layer does not overlap the first upper electrode layer.

Now, details about the respective processes of this embodiment are described. In this embodiment, the step of patterning the organic compound layer and the first upper electrode layer includes the following steps:

(C1) a step of forming a resist layer on the first upper electrode layer;
(C2) a step of processing the resist layer into a resist pattern having a predetermined shape by photolithography; and
(C3) a step of removing a part of the organic compound layer and the first upper electrode layer by etching through the use of the resist pattern.

It should be noted that a process involving utilizing a lift-off layer described in Embodiment 1 may be used instead of the steps (C1) to (C3).

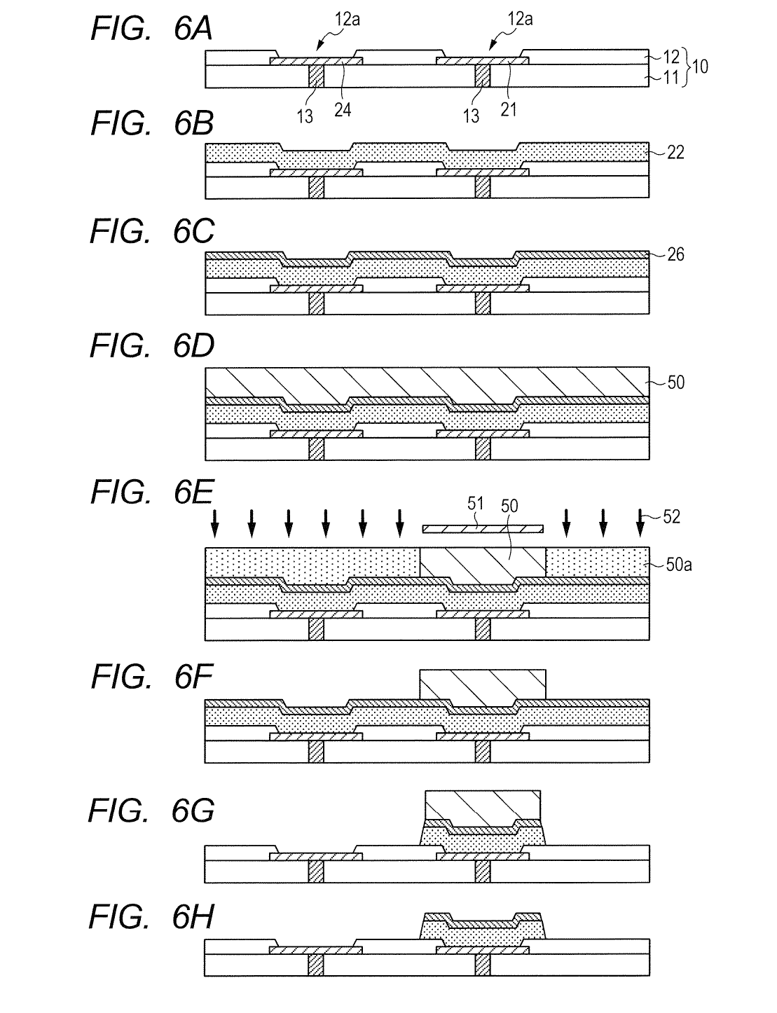

FIGS. 6A to 6O are schematic sectional views for illustrating a method of manufacturing an organic light emitting device according to Embodiment 2 of the present invention.

(2-1) Step of Forming Substrate (FIG. 6A)

First, a substrate to be used for manufacturing the organic light emitting device is produced (FIG. 6A). The substrate 10 to be used in this embodiment (Embodiment 2) includes at least the interlayer insulating layer 11 and the pixel separation film 12. Here, in the substrate 10 illustrated in FIG. 6A, the lower electrode 21 and the wiring connecting portion 24 are each arranged in a predetermined position or region on the interlayer insulting layer 11, and the ends of the lower electrode 21 and the wiring connecting portion 24 are covered with the pixel separation film 12 as an emission region defining member. In addition, the pixel separation film 12 has an opening 12a formed in each of: a region corresponding to the emission pixel 20; and the position at which the wiring connecting portion 24 and the upper electrode 23 are in contact with each other. It should be noted that the substrate 10 may be mounted with a control circuit for controlling the driving of the organic light emitting device, though the circuit is not illustrated in FIG. 6A. Here, when the substrate 10 includes the control circuit, a contact hole 13 is formed in part of the interlayer insulating layer 11 for the purpose of securing electrical connection between the control circuit and the lower electrode 21 or the wiring connecting portion 24.

A constituent material for the interlayer insulating layer 11 forming the substrate 10 illustrated in FIG. 6A is not particularly limited, but a material formed of silicon nitride (SiN) or silicon oxide (SiO) excellent in insulating property is preferred.

A constituent material for the lower electrode 21 to be provided on the interlayer insulating layer 11 is appropriately selected depending on the function of the lower electrode 21 for light emitted from an emission layer (whether the electrode transmits the light or reflects the light). In the case where the light emitted from the emission layer is to be reflected at the lower electrode 21, the lower electrode 21 is an electrode layer having light reflectivity. In such case, the constituent material for the lower electrode 21 is preferably a metal material having high light reflectivity, such as aluminum (Al) or silver (Ag), but Ti or TiN is sometimes used for reducing (an increase in contact resistance due to) surface oxidation. In such case, however, the structure of the lower electrode 21 is not limited to a single layer formed of the metal material having light reflectivity. A laminated electrode film formed of the layer formed of the metal material having light reflectivity and a layer formed of a transparent conductive material such as ITO or indium zinc oxide can also be adopted as the lower electrode 21. In the case where the light emitted from the emission layer is to be transmitted through the lower electrode 21, the lower electrode 21 is an electrode layer having a light transmitting property. In such case, examples of the constituent material for the lower electrode 21 include transparent conductive materials such as ITO and indium zinc oxide.

When the wiring connecting portion 24 is formed simultaneously with the lower electrode 21, a constituent material for the wiring connecting portion 24 is the same as that for the lower electrode 21. Meanwhile, in the present invention, the lower electrode 21 and the wiring connecting portion 24 can each be formed by a separate process. In such case, the constituent material for the wiring connecting portion 24 may be different from the constituent material for the lower electrode 21.

The contact hole 13 to be formed in a predetermined region of the interlayer insulating layer 11 is filled with a connection wiring member for electrically connecting a wiring or circuit (not shown) present below the interlayer insulating layer 11 to the lower electrode 21 or the wiring connecting portion 24. The connection wiring member is, for example, a material having high conductivity, but is not particularly limited in the present invention.

A constituent material for the pixel separation film 12 is not particularly limited as long as the material has an insulating property. However, when the film is formed of organic matter, a material using polyimide as a main component is preferred, and when the film is formed of inorganic matter, silicon nitride (SiN), silicon oxide (SiO), or the like is preferred.

(2-2) Step of Forming Organic Compound Layer (FIG. 6B)

After the substrate 10 has been produced, the organic compound layer is formed on the substrate 10 (FIG. 6B). It should be noted that at the time of the formation of the organic compound layer, the same process as the process described in Embodiment 1 can be used.

(2-3) Step of Forming First Upper Electrode Layer (FIG. 6C)

After the organic compound layer 22 has been formed, the upper electrode 23 is formed on the organic compound layer 22. It should be noted that the upper electrode 23 to be formed in this embodiment is a laminated electrode obtained by laminating the first upper electrode layer 26 and the second upper electrode layer 27. Here, when the upper electrode 23 is an anode, a hole as a positively charged carrier is injected from the upper electrode 23 into the organic compound layer 22, and when the upper electrode 23 is a cathode, an electron as a negatively charged carrier is injected from the upper electrode 23 into the organic compound layer 22.

A constituent material for the first upper electrode layer 26 is appropriately selected depending on the function of the first upper electrode layer 26 for light emitted from the emission layer (whether the electrode layer transmits the light or reflects the light). In the case where the light emitted from the emission layer is to be reflected at the first upper electrode layer 26, the first upper electrode layer 26 is an electrode layer having a light reflecting property. In such case, the constituent material for the first upper electrode layer 26 is preferably a metal material having a high light reflecting property, such as aluminum (Al) or silver (Ag), but Ti or TiN is sometimes used for reducing (an increase in contact resistance due to) surface oxidation. In such case, however, the construction of the first upper electrode layer 26 is not limited to a single layer formed of the metal material having a light reflecting property. A laminated electrode film formed of the layer formed of the metal material having a light reflecting property and a layer formed of a transparent conductive material such as ITO or indium zinc oxide can also be adopted as the first upper electrode layer 26. In the case where the light emitted from the emission layer is to be transmitted through the first upper electrode layer 26, the first upper electrode layer 26 is an electrode layer having a light transmitting property. In such case, examples of the constituent material for the first upper electrode layer 26 include transparent conductive materials such as ITO and indium zinc oxide. In addition, it has been known that a layer formed of any such material is much denser than the organic compound layer 22, and has gas permeability much lower than that of the organic compound layer. Accordingly, when an end of the organic compound layer 22 is covered with the first upper electrode layer 26 at the stage where the first upper electrode layer and the underlying layers are formed, the organic compound layer 22 present below the first upper electrode layer 26 is protected from the permeation of water or a gas such as oxygen.

(2-4) Step of Patterning Organic Compound Layer and First Upper Electrode Layer (FIG. 6D to FIG. 6H)

After the organic compound layer 22 and the first upper electrode layer 26 have been formed on the entire surface of the substrate 10 including the lower electrode 21, the organic compound layer 22 and the first upper electrode layer 26 are processed by a method to be described below. First, the resist layer 50 formed of a positive resist is applied and formed (FIG. 6D), and a region to be removed by etching is exposed to the exposure light 52 through the photomask 51 (FIG. 6E) and developed (FIG. 6F). Thus, a resist pattern is formed. Next, the resist pattern is used as a protective film, and the first upper electrode layer 26 and the organic compound layer 22 that are exposed without being covered with the resist pattern are each removed by etching (FIG. 6G). Next, the resist pattern is removed, and the remainder is washed and dried. Thus, the patterning of the organic compound layer 22 and the first upper electrode layer 26 is completed (FIG. 6H). It should be noted that the drying is performed because of the following reason: part of water to be used in the washing step to be performed after the removal of the resist pattern may adsorb to the organic compound layer 22 or the insulating layer of a base circuit, and hence the water needs to be desorbed.

When the organic compound layer 22 and the first upper electrode layer 26 are processed by the photolithography process described above, the tan(θ) (tan(θ₃)) described with reference to FIG. 3 for each of the ends of the organic compound layer 22 and the first upper electrode layer 26 that have been processed becomes 0.2 or more. Accordingly, an unnecessary region in a layout can be reduced.

(2-5) Steps of Forming and Patterning Second Upper Electrode Layer (FIG. 6I to FIG. 6M)

After the processing of the organic compound layer 22 and the first upper electrode layer 26, the second upper electrode layer 27 is formed on the first upper electrode layer 26 (FIG. 6I). Here, the second upper electrode layer 27 is formed over the entire surface of the substrate 10 as illustrated in FIG. 6I, and hence the first upper electrode layer 26 is electrically connected to the wiring connecting portion 24 by the second upper electrode layer 27.

The same material as that for the first upper electrode layer 26 can be used as a constituent material for the second upper electrode layer 27. Examples thereof include a metal material such as Al or Ag, and a transparent conductive material such as ITO or indium zinc oxide. In addition, the second upper electrode layer 27 may be a layer formed of the metal material or the transparent conductive material, or may be a laminate obtained by laminating a layer formed of the metal material and a layer formed of the transparent conductive material.

After the second upper electrode layer 27 has been formed, the second upper electrode layer 27 is patterned into a predetermined shape by patterning involving using a positive resist and etching (FIG. 6J to FIG. 6M). When such formation is performed, an end of the organic compound layer 22 is covered with the upper electrode 23 formed of the first upper electrode layer 26 and the second upper electrode layer 27. Thus, the penetration of water or oxygen from an end of a film serving as the organic compound layer 22 can be suppressed, and hence high durability can be obtained.

(2-6) Sealing Step (FIG. 6N and FIG. 6O)

After the upper electrode 23 has been formed, the organic light emitting element and wiring connecting portion 24 forming the organic light emitting device are sealed (FIG. 6N and FIG. 6O). When the sealing is performed, the same method as the method described in Embodiment 1 can be adopted.

In the present invention, part of the manufacturing processes for organic light emitting devices described in Embodiment 1 and Embodiment 2 may be appropriately combined with each other, or part of the processes may be appropriately replaced with each other. When the organic light emitting device 1 of FIG. 1 is manufactured, the organic compound layer 22 is formed by, for example, utilizing a lift-off layer having a predetermined pattern shape like Embodiment 1, but a formation process for the organic compound layer 22 is not limited thereto. Like, for example, Embodiment 2, the organic compound layer 22 may be patterned by utilizing a resist layer having a predetermined pattern shape after the film serving as the organic compound layer 22 has been formed. In addition, when the organic light emitting device 2 of FIG. 4 is manufactured, the organic compound layer 22 and first upper electrode layer 26 forming the organic light emitting device 2 may be formed by utilizing the lift-off layer having a predetermined pattern shape described in Embodiment 1.

[Active Element]

The organic light emitting device according to the present invention may further include an active element for controlling the light emission of the organic light emitting element that forms the organic light emitting device. Examples of the active element include a transistor and a switching element such as an MIM element.

The active element to be connected to the organic light emitting element may contain an oxide semiconductor in an active region of the active element. In addition, the oxide semiconductor that is a constituent material for the active element may be amorphous or crystalline, or a mixture of the two. It should be noted that the term “crystal” as used herein means one of a single crystal, a micro crystal, and a crystal in which a particular axis such as the c-axis is oriented. However, the active element is not limited thereto and may use a mixture of at least two types out of those plurality of types of crystals.

[Application of Organic Light Emitting Device]

Next, the application of the organic light emitting device of the present invention is described. The organic light emitting device of the present invention can be used as a constituent member for a display device or lighting device. The device can also be used for a display device including emission pixels having a plurality of emission colors such as red, green, and blue colors. In addition, the device finds use in applications such as an exposure light source for an image forming device of an electrophotographic system, a backlight for a liquid crystal display device, and a light emitting device including a white light source and a color filter. Examples of the color filter include filters that transmit light beams having three colors, i.e., red, green, and blue colors.

A display device of the present invention includes the organic light emitting device of the present invention in its display portion. The display portion includes a plurality of pixels.

In addition, the pixels each include the organic light emitting device of the present invention and a transistor as an example of an active element (switching element) or amplifying element configured to control emission luminance, and the anode or cathode of the organic light emitting element and the drain electrode or source electrode of the transistor are electrically connected to each other. The display device can be used as an image display device for a PC or the like. The transistor is, for example, a TFT element and the TFT element is formed on, for example, the insulating surface of a substrate.

The display device may be an image information processing device that includes an image input portion configured to input image information from, for example, an area CCD, a linear CCD, or a memory card, and an information processing portion configured to process the image information, and displays an input image on its display portion.

In addition, the display portion of an imaging device or inkjet printer may have a touch panel function. The drive system of the touch panel function is not particularly limited.

In addition, the display device may be used in the display portion of a multifunction printer.

A lighting device is a device configured to light, for example, the inside of a room. The lighting device may emit light having any one of the following colors: a white color (having a color temperature of 4,200 K), a daylight color (having a color temperature of 5,000 K), and colors ranging from blue to red colors.

A lighting device of the present invention includes the organic light emitting device of the present invention and an AC/DC converter circuit (circuit configured to convert an AC voltage into a DC voltage) connected to the organic light emitting device and configured to supply a driving voltage. It should be noted that the lighting device may further include a color filter. In addition, the lighting device of the present invention may include a heat sink for discharging heat in the lighting device to the outside.

An image forming device of the present invention is an image forming device including: a photosensitive member; a charging unit configured to charge the surface of the photosensitive member; an exposing unit configured to expose the photosensitive member to form an electrostatic latent image; and a developing unit configured to supply a developer to the photosensitive member, to thereby develop the electrostatic latent image formed on the surface of the photosensitive member. Here, the exposing unit to be arranged in the image forming device includes the organic light emitting device of the present invention.

In addition, the organic light emitting device of the present invention can be used as a constituent member for an exposing device configured to expose a photosensitive member. An exposing device including the organic light emitting device of the present invention is, for example, an exposing device in which the organic light emitting elements that form the organic light emitting device of the present invention are placed to form a line along a predetermined direction.

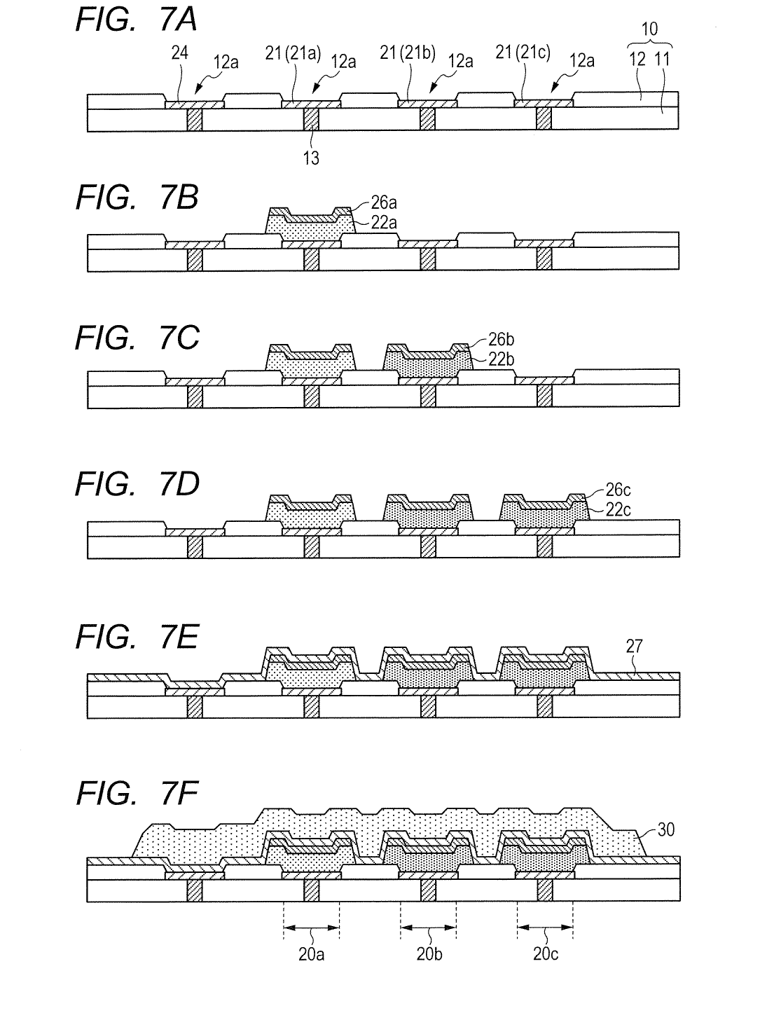

FIG. 8 is a schematic view for illustrating an example of an image forming device that includes the organic light emitting device according to the present invention. An image forming device 6 of FIG. 8 includes a photosensitive member 61, an exposure light source 62, a developing device 64, a charging portion 65, a transferring device 66, a conveying roller 67, and a fixing device 69.

In the image forming device 6 of FIG. 8, light 63 is applied from the exposure light source 62 to the photosensitive member 61, to thereby form an electrostatic latent image on the surface of the photosensitive member 61. In the image forming device 6 of FIG. 8, the exposure light source 62 is the organic light emitting device according to the present invention. In addition, in the image forming device 6 of FIG. 8, the developing device 64 includes toner and the like. In the image forming device 6 of FIG. 8, the charging portion 65 is provided for charging the photosensitive member 61. In the image forming device 6 of FIG. 8, the transferring device 66 is provided for transferring a developed image onto a recording medium 68 such as paper. The recording medium 68 is conveyed by the conveying roller 67 to the transferring device 66. In the image forming device 6 of FIG. 8, the fixing device 69 is provided for fixing the image formed on the recording medium 68.

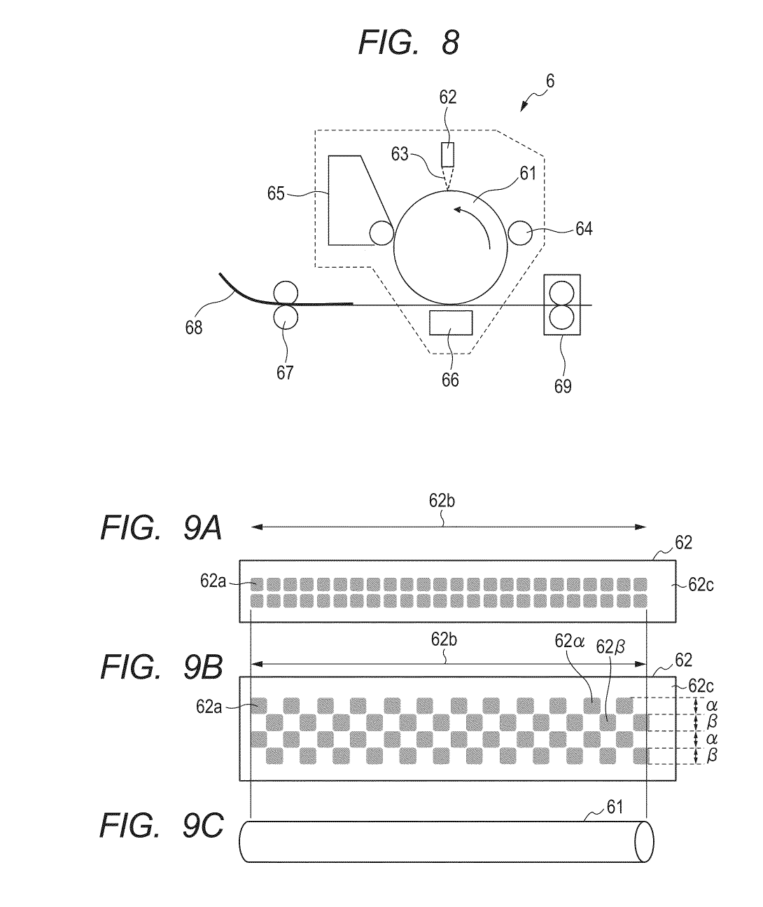

FIG. 9A and FIG. 9B are each a schematic plan view for illustrating a specific example of the exposure light source (exposing device) that forms the image forming device 6 of FIG. 8, and FIG. 9C is a schematic view for illustrating a specific example of the photosensitive member that forms the image forming device 6 of FIG. 8. It should be noted that FIG. 9A and FIG. 9B have the following feature in common: a plurality of emission portions 62a each including the organic light emitting element are placed in line on the exposure light source 62 along the long axis direction of an elongated substrate 62c. In addition, the arrow represented by reference symbol 62b represents a column direction in which the emission portions 62a are arranged. The column direction is the same as the direction of the axis about which the photosensitive member 61 rotates.

Incidentally, FIG. 9A is an illustration of a form in which the emission portions 62a are placed along the axis direction of the photosensitive member 61. On the other hand, FIG. 9B is an illustration of a form in which the emission portions 62a are alternately placed in the column direction in a first column α and a second column β. In FIG. 9B, the first column α and the second column β are placed at different positions in a row direction.

In addition, in FIG. 9B, while a plurality of emission portions 62α are placed at a certain interval in the first column α, the second column β has an emission portion 62β at a position corresponding to an interval between the emission portions 62α in the first column α. That is, in the exposure light source of FIG. 9B, the plurality of emission portions are placed at a certain interval in the row direction as well.

It should be noted that the following rewording is permitted: the exposure light source of FIG. 9B is in a state in which the emission portions (62α, 62β) forming the exposure light source are placed in, for example, a lattice, hound's-tooth, or checkered pattern.

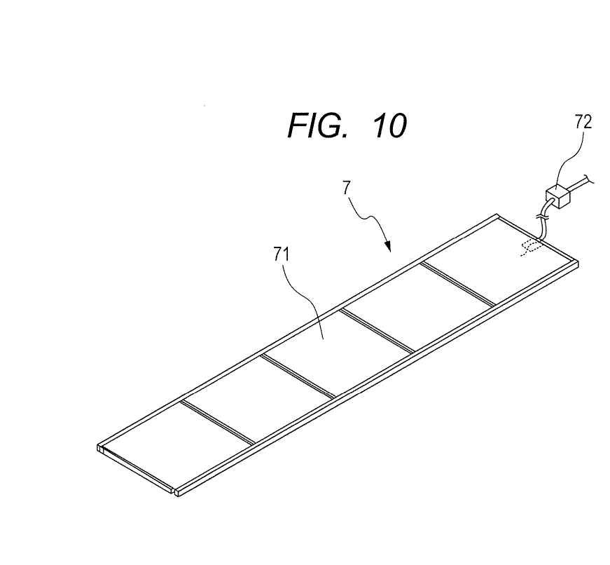

FIG. 10 is a schematic view for illustrating an example of a lighting device that includes the organic light emitting element according to the present invention. A lighting device of FIG. 10 includes an organic light emitting element 71 formed on a substrate (not shown) and an AC/DC converter circuit 72. In the lighting device of FIG. 10, the organic light emitting element 71, which forms the lighting device, is the organic light emitting device of the present invention, or a constituent member for the organic light emitting device of the present invention. In addition, the lighting device of FIG. 10 may include a heat sink (not shown) corresponding to a heat discharging portion for discharging heat in the device to the outside on, for example, a substrate surface on a side opposite to the side on which the organic light emitting element 71 is mounted.

As described above, the driving of the organic light emitting device of the present invention enables display that has good image quality and is stable over a long time period.

Now, the present invention is described in detail by way of Examples. It should be noted that in a step of forming a substrate to be described later, a silicon substrate is used as a starting material, but a transparent substrate such as a glass substrate may be used instead of the silicon substrate. In addition, organic light emitting devices to be manufactured in Examples each include a blue emission layer as an emission layer. However, the present invention is not limited thereto. That is, the organic light emitting device may emit from inside its display region light of a single color (unicolor) or light of two or more different colors (multicolor). The arrangement of emission pixels is also not particularly limited. In addition, an electrode that serves to reflect light (reflective electrode) may be an upper electrode or may be a lower electrode. In addition, any electrode material may be used as a material for an electrode (the lower electrode or the upper electrode) as long as the material satisfies at least the following condition: the material neither deteriorates nor alters when a patterning step such as a photolithography process is performed.

### Example 1

The organic light emitting device 1 of FIG. 1 was manufactured according to the manufacturing process illustrated in FIG. 5A to FIG. 5L.

(1) Step of Forming Substrate (FIG. 5A)

An n-type silicon semiconductor substrate was used as a starting material to produce a substrate with circuits in which base driving circuits were formed through the following typical steps (hereinafter referred to as substrate 10). It should be noted that the substrate with circuits produced here is a substrate having Al wiring, and the production flow of the substrate with circuits can follow a normal semiconductor process. Further, normally employed semiconductor processes such as using Cu wiring, using the double-gate structure in a transistor, and inserting a low-concentration impurity layer between a source-drain and a channel are applicable to the production flow of the substrate with circuits.

1) Forming a LOCOS region by oxidation (LOCOS stands for Local Oxidation of Silicon)
2) Forming a P-type well structure by ion implantation
3) Forming a gate oxide film by oxidation
4) Forming a poly Si gate electrode
5) Forming a source-drain structure by ion implantation
6) Forming an interlayer insulating film and performing CMP
7) Forming a contact hole
8) Filling the contact hole with tungsten and performing CMP
9) Forming Al wiring

### 10) Repeating 6) to 9)

11) Forming an interlayer insulating layer 11 and performing CMP
12) Forming a contact hole 13
13) Filling the contact hole 13 with tungsten and performing CMP
14) Forming a lower electrode 21
15) Forming, if necessary, a pixel separation film 12 that covers the periphery of the lower electrode 21.

Now, the processes 14) and 15) are specifically described. First, Ag was formed into a film having a thickness of 100 nm on the interlayer insulating layer 11 to form a reflective electrode film. Next, indium tin oxide (ITO) was formed into a film having a thickness of 25 nm on the reflective electrode film to form a transparent conductive film. Next, a known photolithography method was used to pattern a laminated electrode film formed of the reflective electrode film (silver film) and the transparent conductive film (ITO film). Thus, the lower electrode 21 and the wiring connecting portion 24 were formed from the same ITO layer. It should be noted that the lower electrode 21 and the wiring connecting portion 24 are connected to the respective drive circuits (not shown) located in a lower layer of the interlayer insulating layer 11, by wiring filling the contact holes 13.

Next, silicon nitride was formed into a film having a thickness of 100 nm on the entire surface of the substrate 10 by CVD film formation to form the pixel separation film 12. Next, a photoresist was formed into a film on the SiN film, and then a resist patterned into a predetermined shape was formed by patterning based on photolithography involving using the photoresist formed into a film. Next, the openings 12a were formed by dry etching involving using the formed resist as a mask and a CF₄ gas so that the lower electrode 21 and the wiring connecting portion 24 were exposed as illustrated in FIG. 5A. Next, a resist residue left on the pixel separation film 12 in the dry etching was removed by dry etching using an oxygen gas. Next, the substrate 10 on which the pixel separation film 12 and the underlying layers had been formed was washed with a commercially available single-wafer washing machine by two-fluid washing, or by pure water washing combined with mega-sonic waves, to wash the surface of the substrate 10. The substrate 10 illustrated in FIG. 5A was thus produced. It should be noted that the substrate 10 produced in this example had a plurality of emission pixels 20 arranged in staggered lines as illustrated in FIG. 5B.

(2) Steps of Forming and Patterning Lift-Off Layer (FIG. 5B to FIG. 5E)

Next, an aqueous solution of polyvinylpyrrolidone (PVP) as a water-soluble polymer material was prepared by mixing the PVP and water. Next, the prepared aqueous solution of the PVP was applied and formed into a film on the substrate 10 by a spin coating method. Next, the film formed of the PVP formed into a film (PVP film) was baked at 110° C. to be dried. Thus, the lift-off layer 53 having a thickness of 500 nm was formed (FIG. 5B).

Next, a commercial photoresist material (manufactured by AZ Electronic Materials, product name: “AZ1500”) was formed into a film by the spin coating method to form a resist film. After that, the resist layer 50 was formed by vaporizing a solvent in the photoresist material (FIG. 5B). At this time, the thickness of the photoresist layer 50 was 1,000 nm.

Next, the substrate 10 on which the photoresist layer 50 and the underlying layers had been formed was set in an exposing device, and was irradiated with the exposure light 52 through the photomask 51 for 40 seconds. Thus, the exposed photoresist layer 50a was obtained (FIG. 5C). After the exposure, development was performed by using a developer (prepared by diluting a product available under the product name “312MIF” from AZ Electronic Materials with water so that a concentration became 50%) for 1 minute (FIG. 5D). Thus, the exposed photoresist layer 50a was removed (FIG. 5E). Next, the lift-off layer 53 that was not covered with the photoresist layer 50 was removed by dry etching involving using the photoresist layer 50 as a mask. At this time, oxygen was used as an etching gas (reactant gas), the flow rate of the etching gas was set to 20 sccm, a pressure in the device was set to 8 Pa, its output was set to 150 W, and a treatment time was set to 10 minutes.

(3) Step of Forming Organic Compound Layer (FIG. 5F)

The organic compound layer 22 was formed above the substrate 10 and the lower electrode 21 by a vacuum deposition method. Organic compounds used in this example are listed below.

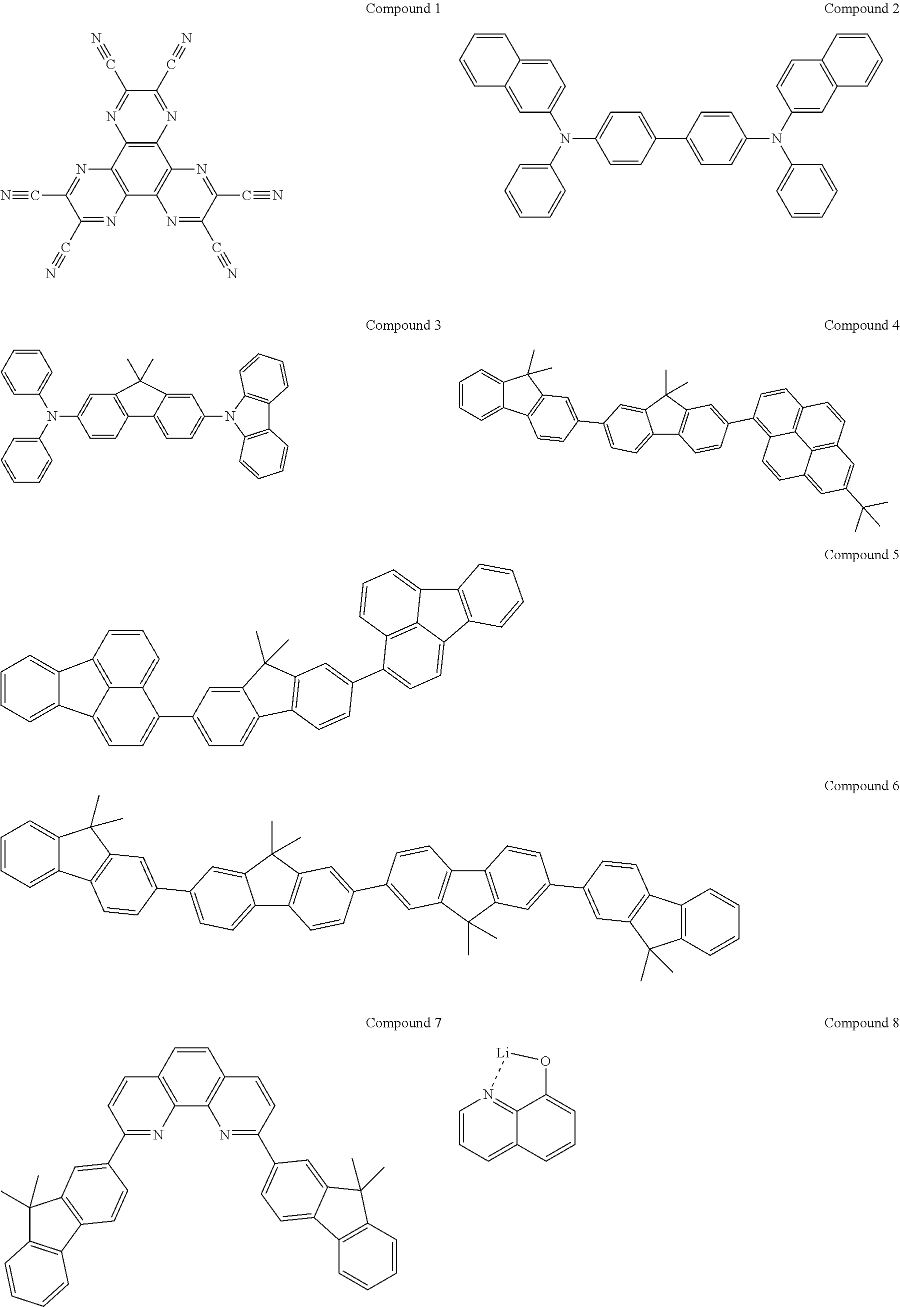

First, Compound 1 was formed into a film having a thickness of 3 nm on the lower electrode 21 to form a hole injection layer. Next, Compound 2 was formed into a film having a thickness of 100 nm on the hole injection layer to form a hole transport layer. Next, Compound 3 was formed into a film having a thickness of 10 nm on the hole transport layer to form an electron blocking layer.

Next, Compound 4 (host) and Compound 5 (guest/light emitting material) were co-deposited from the vapor on the electron blocking layer to form an emission layer having a thickness of 20 nm. It should be noted that the emission layer was formed so that the content of Compound 5 to the whole emission layer was 1 wt %. Further, Compound 6 was formed into a film having a thickness of 10 nm on the emission layer to form a hole blocking layer. Next, Compound 7 was formed into a film having a thickness of 40 nm on the hole blocking layer to form an electron transport layer. Next, Compound 7 and Compound 8 were co-deposited from the vapor on the electron transport layer to form an electron injection layer having a thickness of 15 nm. It should be noted that the electron injection layer was formed so that a weight concentration ratio between Compound 7 and Compound 8 was 1:1.

The organic compound layer 22 in which the hole injection layer, the hole transport layer, the electron blocking layer, the emission layer, the hole blocking layer, the electron transport layer, and the electron injection layer were laminated in the stated order was formed in the manner described above (FIG. 5B).

(4) Lift-Off Step (FIG. 5G)

Next, lift-off was performed by washing the surface of the substrate 10 with pure water. A two-fluid nozzle formed of a nitrogen gas (30 L/min) and pure water (1 L/min) was used in the lift-off. The organic compound layer 22 formed on the lift-off layer 53 was removed by this step. Thus, the organic compound layer 22 was patterned so as to surround an emission pixel, and at the same time, the surface of the wiring connecting portion 24 was exposed by this step. Subsequently, baking was performed under the conditions of 100° C. in a vacuum to dry the substrate 10.

(5) Step of Manufacturing Upper Electrode (FIG. 5H to FIG. 5K)

Next, aluminum (Al) was formed into a film having a thickness of 20 nm over the entire surface of the substrate 10 by the vacuum deposition method to form an Al film. It should be noted that an end of the organic compound layer 22 was covered with the Al film. Next, indium zinc oxide (IZO) was formed into a film having a thickness of 300 nm by sputtering to form a transparent conductive film. It should be noted that a laminated electrode film in which the Al film and the transparent conductive film are laminated in the stated order functions as the upper electrode 23 (FIG. 5H). Next, a photoresist material (manufactured by AZ Electronic Materials, product name: “AZ1500”) was applied onto the transparent conductive film to form a resist film. Next, the photoresist layer 50 was formed by vaporizing a solvent in the resist film (FIG. 5I). At this time, the thickness of the photoresist layer 50 was 1,000 nm.

Next, the substrate 10 on which layers up to the photoresist layer 50 had been formed was set in an exposing device, and was irradiated with the exposure light 52 through a photomask 51 for 40 seconds. Thus, the exposed photoresist layer 50a was obtained (FIG. 5J). After the exposure, development was performed by using a developer (prepared by diluting a product available under the product name “312MIF” from AZ Electronic Materials with water so that a concentration became 50%) for 1 minute. Thus, the exposed photoresist layer 50a was removed. Next, the upper electrode 23 that was not covered with the photoresist layer 50 was removed by dry etching involving using the patterned photoresist layer 50 as a mask. At this time, when the transparent conductive film forming the upper electrode 23 was etched, a mixed gas of methane (CH₄) and hydrogen (H₂) was used as an etching gas, an etching rate was set to 10 nm/min, and an etching time was set to 30 minutes. In addition, when the Al film forming the upper electrode 23 was etched, a mixed gas of boron trichloride (BCl₃) and chlorine (Cl₂) was used as an etching gas, an etching rate was set to 10 nm/sec, and an etching time was set to 3 seconds.

(6) Sealing Step

Next, sealing was performed with a thin film formed of silicon nitride (SiN). Specifically, first, a silicon nitride film having a thickness of 2 μm was formed on the substrate 10, which had undergone steps up to the preceding step (step described in the section (5)), by CVD film formation involving using SiH₄ and N₂ as reactant gases. Next, a pad electrode for external connection (not shown) was exposed by patterning the silicon nitride film through photolithography, and the sealing layer 30 was formed (FIG. 5L). In addition, at this time, all ends of the film serving as the upper electrode 23 patterned in the preceding step were covered with the sealing layer 30.

### Comparative Example 1

The organic light emitting device 1 was manufactured by the same method as that of Example 1 except that in Example 1, the organic compound layer 22 was formed by a vacuum deposition method involving using a mask so as to cover an emission pixel, and the upper electrode 23 was formed into a predetermined shape by sputtering film formation involving using a mask.

### Example 2

The organic light emitting device 1 was manufactured by the same method as that of Example 1 except that in the section (1) of Example 1, the lower electrode 21 was patterned and formed for each pixel by photolithography instead of forming the pixel separation film 12.

### Example 3

When forming the organic compound layer 22 in Example 1, the thickness of the electron transport layer was set to 55 nm, and silver and cesium carbonate were co-deposited from the vapor so that the concentration of cesium carbonate in silver was 10 wt %, a film having a thickness of 4 nm as the electron injection layer. In addition, when forming the upper electrode 23, silver was formed into a film having a thickness of 16 nm, and indium zinc oxide was formed into a film having a thickness of 300 nm by sputtering a thickness of 300 nm, to thereby form a laminated electrode film. Ag forming the laminated electrode film was etched for 10 seconds by dry etching involving using an etching gas containing nitrogen dioxide (NO₂) and ammonia (NH₃), and setting the etching rate to 82 nm/min. An organic light emitting device was manufactured by the same method as that of Example 1 except for the foregoing.

### Example 4

An organic light emitting device was produced by the same method as that of Example 1 except that in Example 1, the substrate 10 (substrate with an electrode) to be used was changed to such a substrate that a distance between an emission pixel and a wiring connecting portion closest to the emission pixel was within 20 μm.

### Example 5

In Example 1, a transparent substrate such as a glass substrate or a resin substrate was used instead of the silicon semiconductor substrate. In addition, polycrystalline Si, amorphous Si, or an oxide semiconductor (for example, IGZO) was used in a layer for forming a transistor. Further, a transparent conductive film formed only of a layer made of ITO alone was used as the lower electrode 21. In addition, a reflective electrode film made of Al was used as the upper electrode 23. Specifically, Al was formed into a film having a thickness of 300 nm by a vacuum deposition method. In addition, conditions for dry etching of the reflective electrode film, which was conducted to form the upper electrode 23, include using an etching gas containing boron chloride (BCl₃) and chlorine (Cl₂), setting the etching rate to the condition of 10 nm/sec, and setting the etching time to 30 seconds. An organic light emitting device was manufactured by the same method as that of Example 1 except for the foregoing.

### Example 6

The organic light emitting device 1 was manufactured by the same method as that of Example 1 except that in Example 1, the substrate with electrodes (substrate 10) was formed so that the emission pixels 20 were arranged on the substrate 10 in a two-dimensional matrix (FIG. 2C).

### Example 7

In Example 1, the substrate with electrodes (substrate 10) was formed so that the emission pixels 20 to be arranged on the substrate 10 each included a first subpixel 20a, a second subpixel 20b, and a third subpixel 20c, and the emission pixels 20 were arranged in a two-dimensional matrix (FIG. 2D). In addition, an organic compound layers for forming the subpixels (20a, 20b, 20c) were formed by vacuum deposition film formation using a mask, while varying the thicknesses of the layers forming each organic compound layer and varying the material for the emission layer from one subpixel to another. An organic light emitting device was manufactured by the same method as that of Example 1 except for the foregoing. It should be noted that in this example, the first subpixel 20a functions as a blue subpixel, the second subpixel 20b functions as a green subpixel, and the third subpixel 20c functions as a red subpixel.

### Example 8

The organic light emitting device 2 of FIG. 4 was manufactured according to the manufacturing process illustrated in FIG. 6A to FIG. 6O. It should be noted that the organic light emitting device manufactured in this example has an emission layer that is a red emission layer, but the present invention is not limited thereto. In addition, in the organic light emitting device manufactured in this example, a plurality of emission pixels are arranged. In the present invention, the arrangement of the emission pixels is also not particularly limited.

(1) Step of Forming Substrate (FIG. 6A)

The substrate 10 was produced by the same method as that of the section (1) of Example 1 through the use of an n-type silicon semiconductor substrate as a starting material.

In this example, the lower electrode 21 was an electrode having a function of reflecting light. Specifically, first, Ag was formed into a film having a thickness of 100 nm on the entire surface of the interlayer insulating layer 11 (including portions where the contact holes 13 were formed). Next, indium tin oxide (ITO) was formed into a film having a thickness of 25 nm on the film made of Ag, to thereby form a laminated electrode film. Next, a known photolithography method was used to pattern the laminated electrode film including the film made of Ag (Ag film) and the film made of ITO (ITO film). Thus, the wiring connecting portion 24 having the same laminated structure as that of the lower electrode 21 was formed along with the lower electrode 21. It should be noted that those electrodes were connected to the respective drive circuits (not shown) located in a lower layer of the substrate 10, by tungsten wiring filling the contact holes 13.

Next, silicon nitride was formed into a film having a thickness of 100 nm by CVD on the entire surface of the substrate 10 (above the lower electrode 21, the wiring connecting portion 24, and the interlayer insulating layer 11). Further, a photoresist was formed into a film on the film made of silicon nitride to form a resist layer. Next, the formed resist layer was patterned by photolithography into a predetermined shape. With the patterned resist layer as a mask, as illustrated in FIG. 6A, dry etching using a CF₄ gas was performed to form the openings 12a in a region on which the lower electrode 21 was to be formed and a region on which the wiring connecting portion 24 was to be formed. Next, a resist residue left on the pixel separation film 12 in the dry etching was removed by dry etching using an oxygen gas. Next, the substrate 10 on which the pixel separation film 12 and the underlying layers had been formed was washed with a commercially available single-wafer washing machine by two-fluid washing, or by pure water washing combined with mega-sonic waves, to wash the surface of the substrate 10. Thus, the substrate 10 illustrated in FIG. 6A was produced. It should be noted that the substrate 10 produced in this example had a plurality of emission pixels 20 arranged in staggered lines as illustrated in FIG. 2B.

(2) Formation of Organic Compound Layer (FIG. 6B)

The organic compound layer 22 was formed by the same method as that of the section (3) of Example 1.

(3) Formation of First Upper Electrode Layer (FIG. 6C)

Next, Al was formed into a film having a thickness of 15 nm on the organic compound layer 22 by vacuum deposition or sputtering to form a semi-transmissive layer. Next, indium zinc oxide was formed into a film having a thickness of 200 nm on the semi-transmissive layer by sputtering to form a transparent electrode layer. It should be noted that a laminated electrode in which the semi-transmissive layer and the transparent electrode layer are laminated in the stated order functions as the first upper electrode layer 26 (FIG. 6C).

(4) Processing (Patterning) of Organic Compound Layer and First Upper Electrode Layer (FIG. 6D to FIG. 6H)

Next, a positive-type photoresist (for example, manufactured by AZ Electronic Materials, product name: “AZ1500”) was applied onto the first upper electrode layer 23 to form a resist film. After that, the resist layer 50 was formed by vaporizing a solvent in the resist film (FIG. 6D). At this time, the thickness of the resist layer 50 was 1,000 nm.

Next, the substrate 10 on which the resist layer 50 and the underlying layers had been formed was set in an exposing device, and was irradiated with the exposure light through a photomask 51 for 40 seconds. Thus, the exposed resist layer 50a was obtained (FIG. 6E). After the exposure, development was performed by using a developer (for example, prepared by diluting a product available under the product name “312MIF” from AZ Electronic Materials with water so that a concentration became 50%) for 1 minute. Thus, the exposed resist layer 50a was removed (FIG. 6F). Next, the first upper electrode layer 23 and the organic compound layer 22 that were not covered with the resist layer 50 were removed by partial dry etching involving using the patterned resist layer 50 as a mask (FIG. 6G). The indium zinc oxide (transparent electrode layer) was etched in this case by plasma etching with CH₄ and H₂ for 20 minutes. In addition, the semi-transmissive layer was etched by plasma etching with BCl₃ and Cl₂ for 10 seconds. Further, the organic compound layer 22 was etched by plasma etching with θ₂ for 10 minutes.

Thus, the organic compound layer 22 and the first upper electrode layer 23 were patterned into substantially the same layout (FIG. 6H).

(5) Formation and Processing (Patterning) of Second Upper Electrode Layer (FIG. 6I to FIG. 6M)

Next, indium zinc oxide was formed into a film having a film thickness of 200 nm by sputtering over the entire surface of the substrate 10 on which the first upper electrode layer 26 and the wiring connecting portion 24 had been formed. Thus, a transparent electrode layer serving as the second upper electrode layer 27 was formed (FIG. 6I). Next, the transparent electrode layer was patterned into a predetermined shape by the same method as that of the section (4) (method of processing the first upper electrode layer 26). Thus, the second upper electrode layer 27 was formed (FIG. 6J to FIG. 6M). It should be noted that the layout of the patterning of the second upper electrode layer 27 at the time of the formation of the second upper electrode layer 27 needs to satisfy the following conditions (5a) and (5b):

(5a) the second upper electrode layer 27 overlaps at least a part of the first upper electrode layer 26; and
(5b) the second upper electrode layer 27 covers the wiring connecting portion 24.

For example, the following mode is available: the second upper electrode layer 27 covers the entirety of the first upper electrode layer 26 as illustrated in FIG. 6M.

(6) Sealing Step (FIG. 6N to FIG. 6O)

Next, the sealing of an organic light emitting element forming an organic light emitting device was performed with a thin film formed of silicon nitride (SiN). Specifically, silicon nitride was formed into a film having a film thickness of 2 μm on the substrate 10 on which the second upper electrode layer 27 patterned into a predetermined shape and the underlying layers had been formed, by CVD film formation involving using SiH₄ and N₂ as reactant gases. Thus, a silicon nitride film serving as the sealing layer 30 was formed (FIG. 6N). After that, a pad electrode for external connection (not shown) was exposed by patterning the silicon nitride film through photolithography. In addition, at this time, all ends of the second upper electrode layer 27 formed in the section (5) were covered with the sealing layer 30 formed of silicon nitride (FIG. 6O).

The organic light emitting device 2 of FIG. 4 was manufactured through the foregoing steps.

### Comparative Example 2

The organic light emitting device 2 was manufactured by the same method as that of Example 8 except that in Example 8, the organic compound layer 22 was formed by a vacuum deposition method involving using a mask so as to cover an emission pixel, and the first upper electrode layer 26 and the second upper electrode layer 27 were formed into a predetermined shape by sputtering film formation involving using a mask.

### Example 9

The organic light emitting device 2 was manufactured by the same method as that of Example 8 except that in the section (1) of Example 8, the lower electrode 21 was patterned and formed for each pixel by photolithography instead of forming the pixel separation film 12.

### Example 10

The organic light emitting device 2 was manufactured by the same method as that of Example 8 except that in Example 8, the substrate 10 (substrate with an electrode) to be used was changed to such a substrate that a distance between an emission pixel and a wiring connecting portion closest to the emission pixel was within 20 μm.

### Example 11

In Example 8, the first upper electrode layer 26 was changed to the following layer (i) or (ii):

(i) a laminate of a layer formed of Ag having a thickness of 15 nm (semi-transmissive Ag layer) and a layer formed of indium zinc oxide having a thickness of 200 nm (transparent electrode layer); and
(ii) a layer formed of indium zinc oxide having a thickness of 215 nm (layer formed only of a transparent electrode layer).

The organic light emitting device 2 was manufactured by the same method as that of Example 8 except for the foregoing. It should be noted that the layers (i) and (ii) can each be appropriately selected depending on a combination of constituent materials for the organic compound layer 22.

### Example 12

The organic light emitting device 2 was manufactured by the same method as that of Example 8 except that in Example 8, the formation of the Ag layer as a reflective electrode was omitted at the time of the formation of the lower electrode 21, and the electrode was formed as a transparent electrode formed only of the ITO layer.

### Example 13

In Example 8, a transparent substrate made of a glass, a resin, or the like was used instead of the silicon semiconductor substrate. In addition, polycrystalline Si, amorphous Si, or an oxide semiconductor (such as IGZO) was used as a layer for forming a transistor. Further, a transparent conductive film formed only of a layer formed of ITO, or a laminated electrode film obtained by laminating a layer formed of Ag (semi-transmissive film) and a layer formed of ITO (transparent conductive film) was used as the lower electrode 21. In addition, the first upper electrode layer 26 was changed to a layer formed of Al or Ag (reflective electrode film), or a laminate formed of a film formed of Al or Ag (reflective electrode film) and a layer formed of indium zinc oxide, the laminate having a thickness of 215 nm (transparent conductive film). The organic light emitting device 2 was manufactured by the same method as that of Example 8 except for the foregoing. It should be noted that the organic light emitting device manufactured in this example is an organic light emitting device of a “bottom emission” type in which light emitted from an emission layer is extracted from a substrate side. In addition, in this example, the constituent material for the first upper electrode layer 26 may be changed from Al or Ag to any other metal material such as Mo or Ti.

### Example 14

In Example 8, a transparent substrate made of a glass, a resin, or the like was used instead of the silicon semiconductor substrate. In addition, polycrystalline Si, amorphous Si, or an oxide semiconductor (such as IGZO) was used as a layer for forming a transistor. Further, a laminated electrode film obtained by laminating a layer formed of Ag (reflecting film) and a layer formed of ITO (transparent conductive film) was used as the lower electrode. In addition, the following layer (i) or (ii) was selected as the first upper electrode layer 26:

(i) a laminate of a layer formed of Ag having a thickness of 15 nm (semi-transmissive Ag layer) and a layer formed of indium zinc oxide having a thickness of 200 nm (transparent electrode layer); and
(ii) a layer formed of indium zinc oxide having a thickness of 215 nm (layer formed only of a transparent electrode layer).

The organic light emitting device 2 was manufactured by the same method as that of Example 8 except for the foregoing. It should be noted that the organic light emitting device 2 manufactured in this example is an organic light emitting device of a “top emission” type in which light emitted from an emission layer is extracted from a side opposite to the substrate 10. In addition, in this example, the constituent material for the first upper electrode layer 26 may be changed from Al or Ag to any other metal material such as Mo or Ti (a constituent material for a semi-transmissive film or a reflecting film).

### Example 15

The organic light emitting device 2 was manufactured by the same method as that of Example 8 except that in Example 8, the substrate with an electrode (substrate 10) was formed so that the emission pixels 20 were arranged on the substrate 10 in a two-dimensional matrix (FIG. 2C).

### Example 16

The organic light emitting device 2 was manufactured so that the emission pixels 20 to be arranged on the substrate 10 each included the first subpixel 20a, the second subpixel 20b, and the third subpixel 20c, and the emission pixels 20 were arranged in a two-dimensional matrix (FIG. 2D).

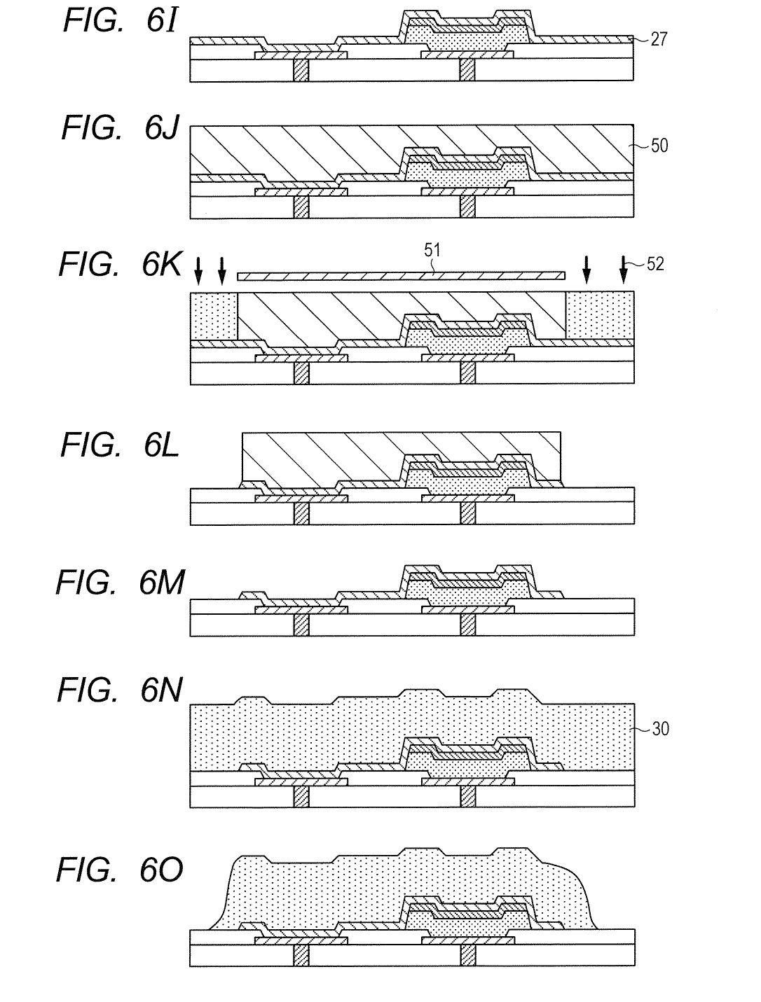

(1) Step of Forming Substrate (FIG. 7A)

The substrate with an electrode (substrate 10) including the lower electrode (21a, 21b, 21c) forming each subpixel (20a, 20b, 20c) and the wiring connecting portion was manufactured in accordance with the process described in the section (1) of Example 8.

(2) Steps of Forming Organic Compound Layer and First Upper Electrode Layer (FIG. 7B to FIG. 7D)

The organic compound layer (22a, 22b, 22c) and first upper electrode layer (26a, 26b, 26c) forming each subpixel (20a, 20b, 20c) were formed in accordance with the processes described in the sections (2) to (4) of Example 8. It should be noted that when each constituent member was formed, an organic material to be used, the thickness of the constituent member, and the position at which the constituent member was formed were changed for each subpixel.

In this example, the first organic compound layer 22a containing a red light emitting organic compound and the first upper electrode layer 26a were formed in the first subpixel 20a (FIG. 7B). In addition, the second organic compound layer 22b containing a green light emitting organic compound and the first upper electrode layer 26b were formed in the second subpixel 20b (FIG. 7C). Further, the third organic compound layer 22c containing a blue light emitting organic compound and the first upper electrode layer 26c were formed in the third subpixel 20c (FIG. 7D).

(5) Formation of Second Upper Electrode Layer (FIG. 7E)

The second upper electrode layer 27 was formed as an electrode common to the respective subpixels (20a, 20b, 20c) in accordance with the process described in the section (5) of Example 8 (FIG. 7E). It should be noted that in this example, the second upper electrode layer 27 may be appropriately processed (patterned) as in the section (5) of Example 8.

(6) Sealing Step (FIG. 7F)

The sealing layer 30 was formed in accordance with the process described in the section (6) of Example 8 (FIG. 7F). It should be noted that in this example, the sealing layer 30 may be appropriately processed (patterned) as in the section (6) of Example 8.

Thus, a display capable of displaying a color in which the red, blue, and green emission regions (subpixels) were arranged in a two-dimensional matrix form as illustrated in FIG. 2D was manufactured.

### EVALUATION RESULTS

An organic light emitting device in which light was extracted from the upper electrode side was obtained in each of Examples 1 to 4, 6 to 8, 9 to 12, and 14 to 16. An organic light emitting device in which light was extracted from the lower electrode side was obtained in each of Examples 5 and 13. In addition, the organic light emitting device obtained in each of Examples 7 and 16 is a full color display that includes pixels each emitting light of one of three colors (R, G, B).

In the organic light emitting device 1 manufactured in each of Examples 1 to 7, the tan(θ) (tan(θ₁)) serving as an indicator of a sectional shape of an end of a film to serve as the organic compound layer 22 was 0.28. In addition, the tan(θ) (tan(θ₂)) serving as an indicator of a sectional shape of an end of a film to serve as the upper electrode 23 was 0.43. That is, the tan(θ) (tan(θ₁) or tan(θ₂)) serving as an indicator of a sectional shape of each of the ends of the organic compound layer 22 and upper electrode 23 forming the organic light emitting device 1 was 0.20 or more.

In the organic light emitting device 2 manufactured in each of Examples 8 to 16, the tan(θ) (tan(θ₃)) serving as an indicator of a sectional shape of an end of the film serving as the organic compound layer 22 was 0.28. In addition, the tan(θ) (tan(θ₃)) serving as an indicator of a sectional shape of an end of a film serving as the first upper electrode layer 26 was 0.31. Further, the tan(θ) (tan(θ₄)) serving as an indicator of a sectional shape of an end of a film serving as the second upper electrode layer 27 was 0.29. That is, the tan(θ) (tan(θ₃) or tan(θ₄)) serving as an indicator of a sectional shape of each of the ends of the organic compound layer 22 forming the organic light emitting device 2, and the first upper electrode layer 26 and second upper electrode layer 27 forming the upper electrode 23 was 0.20 or more. Further, the end taper width of an end of the organic compound layer 22 was 0.7 μm, and each of the end taper widths of the ends of the first upper electrode layer 26 and second upper electrode layer 27 forming the upper electrode 23 was 0.7 μm.

On the other hand, in each of the organic light emitting devices manufactured in Comparative Examples 1 and 2, the end taper width of the organic compound layer 22 was 142 μm, and each of the end taper widths of the ends of the upper electrode 23, the first upper electrode layer 26, and the second upper electrode layer 27 was 228 μm. Therefore, in the organic light emitting device manufactured in each of Examples (1 to 16), the end taper width of the organic compound layer 22 was able to be reduced by 137 μm, and the end taper width of the upper electrode 23 was able to be reduced by 223 μm. It was found from the foregoing that in one side on the substrate of an organic light emitting device whose frame region was defined by an organic compound layer and an upper electrode, the frame region was able to be reduced by a maximum of 360 μm.

In addition, the organic light emitting device 1 manufactured in each of Examples 1 to 8 was found to be a long-life light emitting device because of the following reason: an end of the organic compound layer 22 was covered with the upper electrode 23 and hence the deterioration of an emission pixel portion due to the permeation of moisture or oxygen was prevented. Similarly, the organic light emitting device 2 manufactured in each of Examples 9 to 16 was found to be a long-life light emitting device because of the following reason: the end of the organic compound layer 22 was covered with the upper electrode 23 formed of the first upper electrode layer 26 and the second upper electrode layer 27, and hence the deterioration of the emission pixel portion due to the permeation of moisture or oxygen was suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-124480, filed Jun. 17, 2014, Japanese Patent Application No. 2014-124481, filed Jun. 17, 2014 and Japanese Patent Application No. 2015-075000, filed Apr. 1, 2015 which are hereby incorporated by reference herein in their entirety.

What is claimed is:

1. An organic light emitting device, comprising:
a substrate; and
a lower electrode, an organic compound layer including an emission layer, and an upper electrode sequentially provided on the substrate,
wherein:
the organic compound layer covers the lower electrode;
the upper electrode covers the organic compound layer;
the upper electrode is electrically connected to a wiring connecting portion provided in the substrate; and
when an angle formed between a tilt of a section of an end in at least a partial region of the organic compound layer and a surface of the substrate is represented by θ₁, the following formulas (1) and (2) are satisfied:
tan(θ₁)=d₁/d₂ (1)
tan(θ₁)≧0.2 (2)
in the formula (1), d₁ represents a thickness of the organic compound layer and d₂ represents a taper width of the section of the end of the organic compound layer.

2. The organic light emitting device according to claim 1, wherein when an angle formed between a tilt of a section of an end of the upper electrode and the surface of the substrate is represented by θ₂, the following formulas (3) and (4) are satisfied:
tan(θ₂)=d₃/d₄ (3)
tan(θ₂)≧0.2 (4)
in the formula (3), d₃ represents a thickness of the upper electrode and d₄ represents a taper width of the section of the end of the upper electrode.

3. The organic light emitting device according to claim 1, wherein:
the upper electrode comprises a first upper electrode layer and a second upper electrode layer in the stated order;
a planar pattern of the organic compound layer is substantially identical to a planar pattern of the first upper electrode layer;
at least a part of the second upper electrode layer overlaps the first upper electrode layer; and
the second upper electrode layer is electrically connected to the wiring connecting portion provided in the substrate in a region in which the second upper electrode layer does not overlap the first upper electrode layer.

4. The organic light emitting device according to claim 3, wherein when an angle formed between a tilt of a section of an end of the first upper electrode layer and the surface of the substrate is represented by θ₃, the following formulas (5) and (6) are satisfied:
tan(θ₃)=d₅/d₆ (5)
tan(θ₃)≧0.2 (6)
in the formula (5), d₅ represents a thickness of the first upper electrode layer and d₆ represents a taper width of the section of the end of the first upper electrode layer.

5. The organic light emitting device according to claim 3, wherein when an angle formed between a tilt of a section of an end of the second upper electrode layer and the surface of the substrate is represented by θ₄, the following formulas (7) and (8) are satisfied:
tan(θ₄)=d₇/d₈ (7)
tan(θ₄)≧0.2 (8)
in the formula (7), d₇ represents a thickness of the second upper electrode layer and d₈ represents a taper width of the section of the end of the second upper electrode layer.

6. The organic light emitting device according to claim 3, wherein the second upper electrode layer is formed to cover the first upper electrode layer.

7. The organic light emitting device according to claim 1, wherein one of the taper width of the section of the end of the organic compound layer and a taper width of a section of an end of the upper electrode is 5 μm or less.

8. The organic light emitting device according to claim 1, further comprising a sealing layer formed to cover the upper electrode,
wherein a part of the sealing layer has an opening for forming an external connection terminal portion.

9. A display device, comprising:
the organic light emitting device of claim 1; and
an active element connected to the organic light emitting device.

10. An image information processing device, comprising:
an input portion configured to input image information;
an information processing portion configured to process the image information; and
a display portion configured to display an image,
wherein the display portion comprises the display device of claim 9.

11. A lighting device, comprising:
the organic light emitting device of claim 1; and
an AC/DC converter configured to supply a driving voltage to the organic light emitting device.

12. A lighting device, comprising:
the organic light emitting device of claim 1; and
a heat sink,
wherein the heat sink is configured to dissipate heat inside the lighting device to an outside.

13. An image forming device, comprising:
a photosensitive member;
a charging portion configured to charge the photosensitive member;
an exposure portion configured to expose the photosensitive member; and
a developing portion configured to supply a developer to the photosensitive member,
wherein the exposure portion comprises the organic light emitting device of claim 1.

14. An exposing device, which is configured to expose a photosensitive member, the exposing device comprising a plurality of organic light emitting devices, at least one of which comprises the organic light emitting device of claim 1,
wherein the plurality of organic light emitting devices are arranged in a single line along a long axis direction of the photosensitive member.

15. A method of manufacturing an organic light emitting device comprising a substrate, and a lower electrode, an organic compound layer including an emission layer, and an upper electrode sequentially provided on the substrate, the method comprising:
providing an emission defining region for determining an emission region on the lower electrode;
forming the organic compound layer on the lower electrode;
patterning the organic compound layer; and
forming the upper electrode on the organic compound layer,
wherein when an angle formed between a tilt of a section of an end of the organic compound layer and a surface of the substrate is represented by θ₁, the following formulas (1) and (2) are satisfied:
tan(θ₁)=d₁/d₂ (1)
tan(θ₁)≧0.2 (2)
in the formula (1), d₁ represents a thickness of the organic compound layer and d₂ represents a taper width of the section of the end of the organic compound layer.

16. The method of manufacturing an organic light emitting device according to claim 15, wherein the patterning the organic compound layer comprises:
forming a lift-off layer before the forming the organic compound layer;
patterning the lift-off layer through use of photolithography in such a manner that at least the lift-off layer formed in a region in which the pad portion is arranged remains; and
removing the lift-off layer together with the organic compound layer provided on the lift-off layer after the forming the organic compound layer.

17. The method of manufacturing an organic light emitting device according to claim 15, wherein the patterning the organic compound layer comprises:
forming a lift-off layer after the forming the organic compound layer;
performing patterning through use of photolithography in such a manner that at least the lift-off layer and the organic compound layer in the emission region remain; and
removing the lift-off layer to expose a surface of the organic compound layer.

18. A method of manufacturing an organic light emitting device comprising a substrate, and a lower electrode, an upper electrode, and an organic compound layer including an emission layer placed between the lower electrode and the upper electrode, the lower electrode, the upper electrode, and the organic compound layer being sequentially provided on the substrate, the method comprising:
forming an emission region defining member for determining an emission region on the lower electrode;
continuously forming the organic compound layer and a first upper electrode layer on the lower electrode;
patterning the organic compound layer and the first upper electrode layer; and
forming a second upper electrode layer on the first upper electrode layer,
a planar pattern of the organic compound layer being substantially identical to a planar pattern of the first upper electrode layer;
at least a part of the second upper electrode layer overlapping the first upper electrode layer; and
the second upper electrode layer being electrically connected to a wiring connecting portion provided in the substrate in a region in which the second upper electrode layer does not overlap the first upper electrode layer.

19. The method of manufacturing an organic light emitting device according to claim 18, wherein the patterning the organic compound layer and the first upper electrode layer comprises:
providing a resist on the first upper electrode layer;
processing the resist into a resist pattern having a predetermined shape by photolithography; and
removing a part of the organic compound layer and the first upper electrode layer by etching through use of the resist pattern.

20. The method of manufacturing an organic light emitting device according to claim 18, wherein the patterning the organic compound layer and the first upper electrode layer comprises:
forming a lift-off layer in a region from which the organic compound layer and the first upper electrode layer are removed before forming a film serving as the organic compound layer;
continuously forming the organic compound layer and the first upper electrode layer; and
etching the lift-off layer to remove the lift-off layer, and the organic compound layer and the first upper electrode layer provided on the lift-off layer.
